(19) United States
(12) Patent Application Publication
(10) Pub. No.: US 2024/0180002 A1
(43) Pub. Date: May 30, 2024

(54) DISPLAY DEVICE, ELECTRONIC DEVICE, AND METHOD OF MANUFACTURING DISPLAY DEVICE

(71) Applicant: SONY SEMICONDUCTOR SOLUTIONS CORPORATION, Kanagawa (JP)

(72) Inventor: Tomoyoshi ICHIKAWA, Kanagawa (JP)

(73) Assignee: SONY SEMICONDUCTOR SOLUTIONS CORPORATION, Kanagawa (JP)

(21) Appl. No.: 18/551,644

(22) PCT Filed: Mar. 4, 2022
(86) PCT No.: PCT/JP2022/009435

§ 371 Date: Sep. 21, 2023

(30) Foreign Application Priority Data
Mar. 31, 2021 (JP) 2021-061660

(51) Int. Cl. H10K 59/80; H10K 59/12; H10K 59/35

(52) U.S. Cl. CPC H10K 59/876; H10K 59/1201; H10K 59/35

(57) ABSTRACT

Provided are a display device and an electronic device in which a level difference between front sub-pixels can be suppressed even if a resonator structure is included, and a method of manufacturing the display device. A display device includes a plurality of sub-pixels corresponding to a plurality of color types, in which each of the sub-pixels includes a light emitting element including a first electrode, an organic layer, and a second electrode, and in at least the sub-pixels corresponding to one color type, a resonator structure that causes emitted light from the organic layer to resonate is formed and a refractive index adjustment layer is included in at least one of the first electrode or the second electrode.

### TECHNICAL FIELD

The present disclosure relates to a display device, an electronic device, and a method of manufacturing a display device.

### BACKGROUND ART

In a display device such as an organic EL display, a microcavity structure (resonator structure) is known as a technology contributing to color reproducibility and high efficiency according to a color type of a sub-pixel as described in Patent Document 1. In the resonator structure described in Patent Document 1, a film thickness of an interlayer insulating film (optical path length adjusting layer) between a reflector and a lower transparent electrode is set to a value that satisfies a resonance condition determined according to the color type of the sub-pixel.

### CITATION LIST

### Patent Document

Patent Document 1: Japanese Patent Application Laid-Open No. 2015-26561

### SUMMARY OF THE INVENTION

### Problems to be Solved by the Invention

In the resonator structure as disclosed in Patent Document 1, since the film thickness of the optical path adjustment layer varies according to difference in the color type of the sub-pixel, a level difference based on a film thickness difference of the optical path adjustment layer may be generated between sub-pixels in each layer formed above the optical path adjustment layer. When the level difference generated between the sub-pixels increases, there is a concern that light extraction efficiency and color purity are affected. Thus, in a display device having a resonator structure, there is room for improvement in terms of suppressing a level difference between sub-pixels.

The present disclosure has been made in view of the above-described points, and an object of the present disclosure is to provide a display device and an electronic device in which a level difference between sub-pixels can be suppressed even if the devices have a resonator structure, and a method of manufacturing the display device.

### Solutions to Problems

The present disclosure is, for example, (1) a display device including
a plurality of sub-pixels corresponding to a plurality of color types, in which
each of the sub-pixels includes a light emitting element including a first electrode, an organic layer, and a second electrode, and
in at least the sub-pixels corresponding to one color type, a resonator structure that causes emitted light from the organic layer to resonate is formed and a refractive index adjustment layer is included in at least one of the first electrode or the second electrode.

The present disclosure may be, for example, (2) an electronic device including the display device according to (1) described above.

Furthermore, the present invention is, for example, (3) a method of manufacturing a display device, including:
forming an optical adjustment layer on a transparent conductive layer;
collectively dividing the optical adjustment layer at a pitch corresponding to each of sub-pixels; and
forming a semi-transmissive reflective layer to cover the optical adjustment layer divided.

### BRIEF DESCRIPTION OF DRAWINGS

FIG. 1 is a cross-sectional view for describing an implementation example of a display device according to a first embodiment.

FIG. 2A is a plan view for describing one of implementation examples of the display device. FIG. 2B is a plan view illustrating an arrangement of sub-pixels in a region XS surrounded by a broken line in FIG. 2A.

FIGS. 3A and 3B are cross-sectional views illustrating examples of a light emitting element.

FIGS. 4A to 4E are cross-sectional views for describing a method of manufacturing the display device according to the first embodiment.

FIGS. 5A to 5E are cross-sectional views for describing the method of manufacturing the display device according to the first embodiment.

FIG. 6A is a cross-sectional view for describing an implementation example of the display device according to the first embodiment. FIG. 6B is a cross-sectional view for describing a modification of the display device according to the first embodiment.

FIGS. 7A and 7B are a cross-sectional views for describing modifications of the display device according to the first embodiment.

FIGS. 8A and 8B are cross-sectional views for describing modifications of the display device according to the first embodiment.

FIGS. 9A and 9B are cross-sectional views for describing modifications of the display device according to the first embodiment.

FIG. 10 is a cross-sectional view for describing an implementation example of a display device according to a second embodiment.

FIG. 11A is a plan view for describing an arrangement of sub-pixels of the display device according to the second embodiment. FIG. 11B is a cross-sectional view for describing an implementation example of the display device according to the second embodiment.

FIG. 12 is a diagram for describing a display device equivalent to the display device according to the second embodiment.

FIGS. 13A to 13C each are cross-sectional views for describing an implementation example of an optical adjustment layer according to the second embodiment.

FIGS. 14A to 14C are cross-sectional views for describing a method of manufacturing the display device according to the second embodiment.

FIGS. 15A to 15C are cross-sectional views for describing the method of manufacturing the display device according to the second embodiment.

FIG. 16 is a cross-sectional view for describing a modification of the display device according to the second embodiment.

FIGS. 17A and 17B are cross-sectional views for describing modifications of the display device according to the second embodiment.

FIGS. 18A and 18B are cross-sectional views for describing modifications of the display device according to the second embodiment.

FIGS. 19A and 19B are cross-sectional views for describing modifications of the display device according to the second embodiment.

FIGS. 20A and 20B are cross-sectional views for describing modifications of the display device according to the second embodiment.

FIGS. 21A and 21B each are a diagram for describing an implementation example (third embodiment) of a layout of sub-pixels of a display device.

FIGS. 22A and 22B each are a diagram for describing an implementation example (third embodiment) of the layout of the sub-pixels of the display device.

FIG. 23A is a cross-sectional view for describing an implementation example of a display device according to a fourth embodiment. FIG. 23B is a cross-sectional view for describing an implementation example of a display device according to a fifth embodiment.

FIG. 24A is a cross-sectional view for describing an implementation example of a display device according to a sixth embodiment. FIG. 24B is a cross-sectional view for describing an implementation example of a display device according to a seventh embodiment.

FIGS. 25A and 25B are diagrams for describing an implementation example of an electronic device using a display device.

FIG. 26 is a diagram for describing an implementation example of the electronic device using a display device.

FIG. 27 is a diagram for describing an implementation example of the electronic device using a display device.

### MODE FOR CARRYING OUT THE INVENTION

Hereinafter, an implementation example and the like according to the present disclosure will be described with reference to the drawings. Note that, the description will be made in the following order. In the present specification and the drawings, configurations having substantially the same functional configuration are denoted by the same reference numerals, and redundant descriptions are omitted.

Note that, the description will be given in the following order.
1. First Embodiment
2. Second Embodiment
3. Third Embodiment
4. Fourth Embodiment
5. Fifth Embodiment
6. Sixth Embodiment
7. Seventh Embodiment
8. Application examples

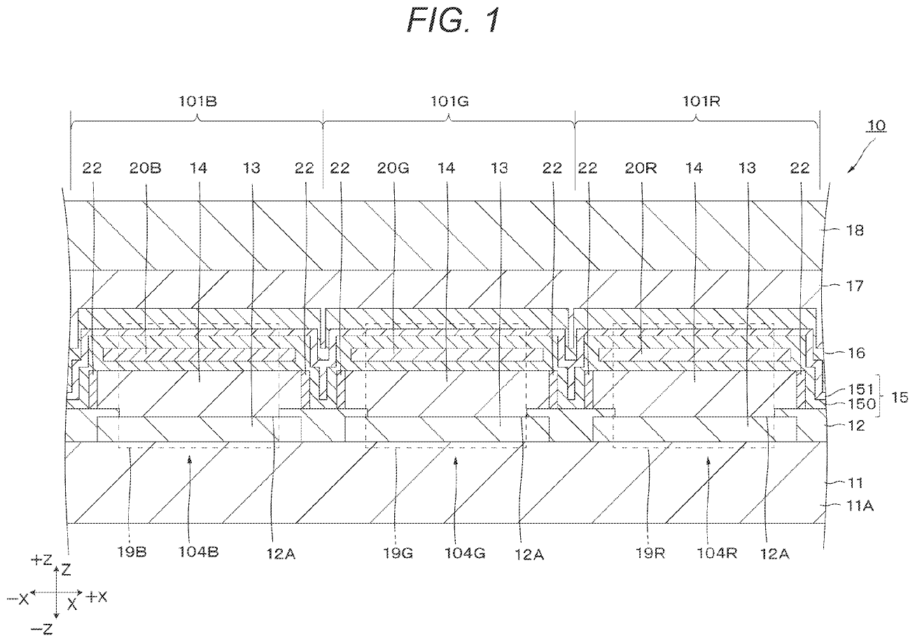

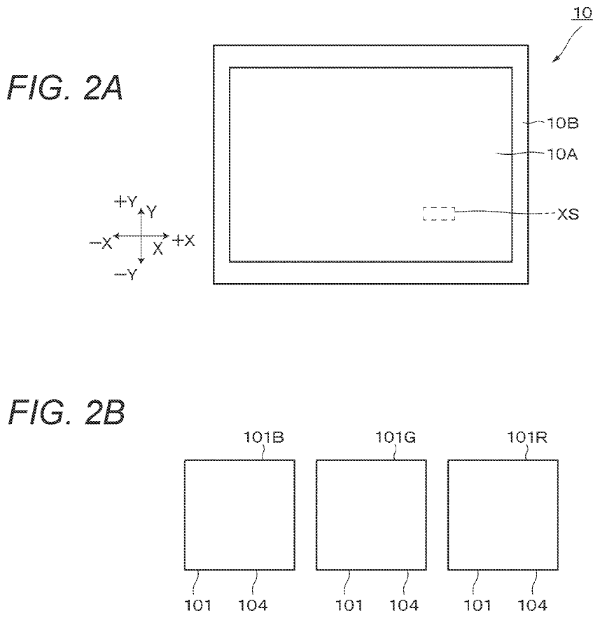

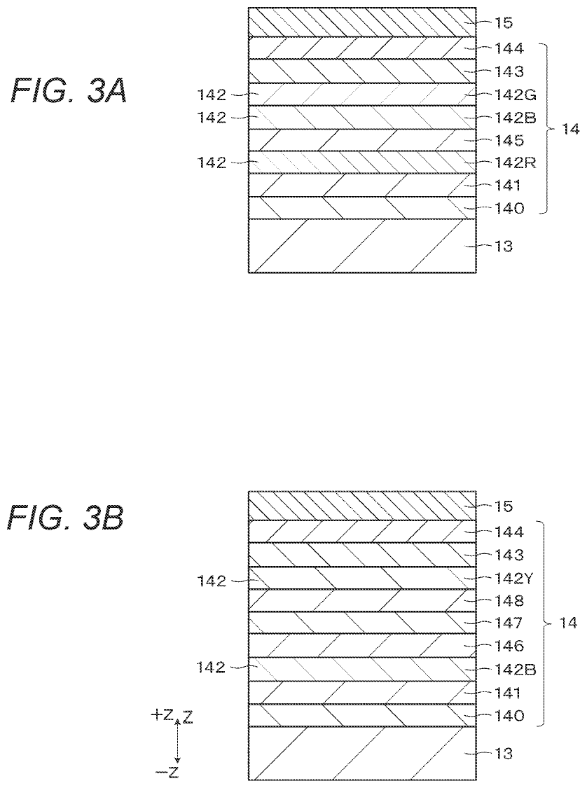

The following description is preferred specific examples of the present disclosure, and the content of the present disclosure is not limited to these embodiments and the like. Furthermore, in the following description, directions of front and back, left and right, up and down, and the like are indicated in consideration of convenience of description, but the content of the present disclosure is not limited to these directions. In examples of FIGS. 1 and 2, it is assumed that the Z-axis direction is the up and down direction (upper side is in a +Z direction, and lower side is in a −Z direction), the X-axis direction is the front and back direction (front side is in a +X direction, and back side is in a −X direction), and the Y-axis direction is the left and right direction (right side is in a +Y direction, and left side is in a −Y direction), and the description will be made on the basis of this. This similarly applies to FIGS. 3 to 11 and FIGS. 14 to 24. A relative magnitude ratio of the size and thickness of each layer illustrated in each drawing of FIG. 1 and the like is described for convenience, and do not limit actual magnitude ratios. This similarly applies to each drawing of FIGS. 2 to 24 regarding the definition and the magnitude ratio regarding these directions.

### 1. First Embodiment

### [1-1. Configuration of Display Device]

FIG. 1 is a cross-sectional view illustrating a configuration example of an organic electroluminescence (EL) display device 10 (hereinafter simply referred to as a “display device 10”) according to an embodiment of the present disclosure. The display device 10 includes a drive substrate 11 and a plurality of light emitting elements 104. Furthermore, the display device 10 has a resonator structure 19. Note that, in FIG. 1, a filling resin layer 17 and a counter substrate 18, which will be described later, are illustrated. In FIGS. 2 to 24, the filling resin layer 17 and the counter substrate 18 are omitted for convenience of description.

The display device 10 is a top emission type display device. In the display device 10, the drive substrate 11 is located on a back surface side of the display device 10, and a direction from the drive substrate 11 toward the light emitting elements 104 (+Z direction) is a front surface side (a display surface side in a display region 10A, an upper surface side) direction of the display device 10. In the following description, in each layer constituting the display device 10, a surface on the display surface side in the display region 10A of the display device 10 is referred to as a first surface (upper surface), and a surface on the back surface side of the display device 10 is referred to as a second surface (lower surface).

### (Configuration Example of Sub-Pixel)

In the example of the display device 10 illustrated in FIG. 1, one pixel includes a combination of a plurality of sub-pixels corresponding to a plurality of color types. In this example, three colors of red, green, and blue are determined as the plurality of color types, and three types of a sub-pixel 101R, a sub-pixel 101G, and a sub-pixel 101B are provided as the sub-pixels. The sub-pixel 101R, the sub-pixel 101G, and the sub-pixel 101B are a red sub-pixel, a green sub-pixel, and a blue sub-pixel, respectively, and display red, green, and blue, respectively. However, the example of FIG. 1 is an example, and the color types of the plurality of sub-pixels are not limited. Furthermore, wavelengths of light corresponding to respective color types of red, green, and blue can be determined as, for example, wavelengths in a range of 610 nm to 650 nm, a range of 510 nm to 590 nm, and a range of 440 nm to 480 nm, respectively. Furthermore, a layout of the individual sub-pixels 101R, 101G, and 101B is a layout arranged side by side in the example of FIG. 2B. Then, the sub-pixels 101R, 101G, and 101B are two-dimensionally provided. FIG. 2B is a diagram illustrating a state in which a partial region in the display surface formed in the display region 10A of FIG. 2A is enlarged. FIG. 2A is a diagram for describing the display region 10A of the display device 10.

In the following description, in a case where the sub-pixels 101R, 101G, and 101B are not particularly distinguished from each other, the sub-pixels 101R, 101G, and 101B are collectively referred to as a sub-pixel 101.

### (Drive Substrate)

The drive substrate 11 is provided with various circuits for driving the plurality of light emitting elements 104 on a substrate 11A. Examples of the various circuits include a drive circuit that controls driving of the light emitting elements 104 and a power supply circuit that supplies power to the plurality of light emitting elements 104 (none of which are illustrated).

The substrate 11A may include, for example, glass or resin having low moisture and oxygen permeability, or may include a semiconductor in which a transistor or the like is easily formed. Specifically, the substrate 11A may be a glass substrate, a semiconductor substrate, a resin substrate, or the like. The glass substrate includes, for example, high strain point glass, soda glass, borosilicate glass, forsterite, lead glass, quartz glass, or the like. The semiconductor substrate includes, for example, amorphous silicon, polycrystalline silicon, monocrystalline silicon, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

A plurality of contact plugs (not illustrated) for connecting the light emitting elements 104 to the various circuits provided on the substrate 11A is provided on the first surface of the drive substrate 11.

### (Light Emitting Element)

In the display device 10, the plurality of light emitting elements 104 is provided on the first surface of the drive substrate 11. In the example of FIG. 1, the light emitting elements 104 are organic electroluminescent elements. Furthermore, in this example, as the plurality of light emitting elements 104, individual light emitting elements 104R, 104G, and 104B are formed to correspond to the individual sub-pixels 101R, 101G, and 101B. The light emitting elements 104R, 104G, and 104B respectively output red, green, and blue light as emitted light from the respective light emitting surfaces. In the present specification, in a case where the types such as the light emitting elements 104R, 104G, and 104B are not particularly distinguished from each other, a term light emitting element 104 is used. The plurality of light emitting elements 104 is, for example, two-dimensionally arranged in a prescribed arrangement pattern such as a matrix shape or the like. In the example of FIG. 2A, the plurality of light emitting elements 104 is laid out two-dimensionally to be arranged in predetermined two directions (X-axis direction and Y-axis direction in FIG. 2A). FIG. 2A is a plan view for describing an implementation example of a formation surface (display surface) of the display region 10A of the display device 10. In FIG. 2A, a reference numeral 10B denotes a region outside the display region 10A.

Each of the light emitting elements 104 includes a first electrode 13, an organic layer 14, and a second electrode 15. The first electrode 13, the organic layer 14, and the second electrode 15 are stacked in this order from the drive substrate 11 side in a direction from the second surface toward the first surface.

### (First Electrode)

A plurality of the first electrodes 13 is provided on the first surface side of the drive substrate 11. The first electrodes 13 are electrically separated from each other for the respective sub-pixels 101 by an insulating layer 12 to be described later. The first electrode 13 is an anode electrode. In the example of FIG. 1, the first electrode 13 also functions as a reflective layer. In this case, the first electrode 13 preferably has as high a reflectance as possible. Moreover, the first electrode 13 preferably includes a material having a large work function to enhance luminous efficiency.

The first electrode 13 includes at least one of a metal layer or a metal oxide layer. For example, the first electrode 13 may include a single layer film of a metal layer or a metal oxide layer, or a laminated film of a metal layer and a metal oxide layer. In a case where the first electrode 13 includes the laminated film, the metal oxide layer may be provided on the organic layer 14 side, or the metal layer may be provided on the organic layer 14 side, but from the viewpoint of including a layer having a high work function adjacent to the organic layer 14, the metal oxide layer is preferably provided on the organic layer 14 side.

The first electrode 13 may include a reflector and a transparent conductive layer. This can be implemented, for example, by forming the first electrode 13 using a metal layer having light reflectivity as the reflector and a metal oxide film having optical transparency as the transparent conductive layer. Furthermore, the first electrode 13 may be formed with a transparent conductive layer 130, and the reflector may be provided separately from the first electrode 13.

The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

The metal oxide layer includes, for example, at least one of a mixture of indium oxide and tin oxide (ITO), a mixture of indium oxide and zinc oxide (IZO), or titanium oxide (TiO).

### (Insulating Layer)

In the display device 10, as illustrated in FIG. 1, the insulating layer 12 is preferably provided on the first surface side of the drive substrate 11. The insulating layer 12 is provided between the adjacent first electrodes 13, and electrically separates the first electrodes 13 from each other for the respective light emitting elements 104 (that is, for the respective sub-pixels 101). Furthermore, the insulating layer 12 includes a plurality of openings 12A, and the first surfaces of the first electrodes 13 (surfaces facing the second electrode 15) are exposed from the openings 12A. Note that, in the example of FIG. 1 and the like, the insulating layer 12 covers regions from peripheral edge portions to side surfaces (end surfaces) of the first surfaces of the separated first electrodes 13. Then, in this case, the openings 12A are arranged on the first surfaces of the respective first electrodes 13. At this time, the first electrodes 13 are exposed from the openings 12A, and these exposed regions define light emitting regions of the light emitting elements 104. In the present specification, a peripheral edge portion of the first surface of the first electrode 13 refers to a region having a predetermined width from the outer peripheral edge on the first surface side of the individual first electrode 13 toward the inside of the first surface.

The insulating layer 12 includes, for example, an organic material or an inorganic material. The organic material includes, for example, at least one of polyimide or acrylic resin. The inorganic material includes, for example, at least one of silicon oxide, silicon nitride, silicon oxynitride, or aluminum oxide.

(Organic layer)

The organic layer 14 is provided between the first electrode 13 and the second electrode 15. The organic layer 14 is provided as a layer electrically separated for each of the sub-pixels 101 corresponding to respective color types. In the example of FIG. 1, the organic layer 14 is configured to be able to emit white light. However, this does not prohibit an emission color of the organic layer 14 from being other than white, and colors including red, blue, green, and the like may be adopted. That is, the emission color of the organic layer 14 may be, for example, any one of white, red, blue, or green.

For example, as illustrated in FIG. 3A, the organic layer 14 has a configuration in which a hole injection layer 140, a hole transport layer 141, a light emitting layer 142, and an electron transport layer 143 are provided in this order from the first electrode 13 toward the second electrode 15. An electron injection layer 144 may be provided between the electron transport layer 143 and the second electrode 15. The electron injection layer 144 is for increasing electron injection efficiency. Examples of a material of the electron injection layer 144 can include a simple substance of an alkali metal or an alkaline earth metal such as lithium or lithium fluoride, and a compound including the simple substance. Note that, the configuration of the organic layer 14 is not limited thereto, and layers other than the light emitting layer 142 are provided as necessary.

The hole injection layer 140 is a buffer layer for enhancing hole injection efficiency into the light emitting layer 142 and suppressing leakage. Examples of a material of the hole injection layer 140 can include hexaazatriphenylene (HAT). The hole transport layer 141 is for enhancing hole transport efficiency to the light emitting layer 142. Examples of a material of the hole transport layer 141 can include N,N′-di(1-naphthyl)-N,N′-diphenyl-1,1′-biphenyl-4,4′-diamine(α-NPD). The electron transport layer 143 is for enhancing electron transport efficiency to the light emitting layer 142. Examples of a material of the electron transport layer 143 can include aluminum quinolinol, bathophenanthroline, and the like.

The light emitting layer 142 generates light by recombination of electrons and holes when an electric field is applied. The light emitting layer 142 is an organic light emitting layer including an organic light emitting material. The light emitting layer 142 has, for example, a stacked structure (1 stack structure) in which a red light emitting layer 142R, a blue light emitting layer 142B, and a green light emitting layer 142G are stacked. However, as illustrated in FIG. 3A, a light emission separation layer 145 is arranged between the red light emitting layer 142R and the blue light emitting layer 142B.

In the red light emitting layer 142R, when an electric field is applied, some of holes (holes) injected from the first electrode 13 through the hole injection layer 140 and the hole transport layer 141 and some of electrons injected from the second electrode 15 through the electron transport layer 143 are recombined to generate red light. The red light emitting layer 142R includes, for example, at least one of a red light emitting material, a hole transport material, an electron transport material, or both-charges transport material. The red light emitting material may be fluorescent or phosphorescent. Specifically, the red light emitting layer may include, for example, a mixture of 4,4-bis(2,2-diphenylvinin) biphenyl (DPVBi) and 30 wt % of 2,6-bis[(4′-methoxydiphenylamino) styryl]-1,5-dicyanonaphthalene (BSN).

The light emission separation layer 145 is a layer for adjusting injection of carriers into the light emitting layer 142, and electrons or holes are injected into each light emitting layer constituting the light emitting layer 142 through the light emission separation layer 145, whereby light emission balance of colors is adjusted. The light emission separation layer 145 includes, for example, 4,4′-bis[N-(1-naphthyl)-N-phenyl-amino] biphenyl derivative, or the like.

In the blue light emitting layer 142B, when an electric field is applied, some of holes injected from the first electrode 13 through the hole injection layer 140, the hole transport layer 141, and the light emission separation layer 145 and some of electrons injected from the second electrode 15 through the electron transport layer 143 are recombined to generate blue light. The blue light emitting layer 142B includes, for example, at least one of a blue light emitting material, a hole transport material, an electron transport material, or both-charges transport material. The blue light emitting material may be fluorescent or phosphorescent. Specifically, the blue light emitting layer 142B includes, for example, a mixture of DPVBi and 2.5 wt % of 4,4′-bis[2-{4-(N,N-diphenylamino) phenyl} vinyl] biphenyl (DPAVBi).

In the green light emitting layer 142G, when an electric field is applied, some of holes injected from the first electrode 13 through the hole injection layer 140, the hole transport layer 141, and the light emission separation layer 145 and some of electrons injected from the second electrode 15 through the electron transport layer 143 are recombined to generate green light. The green light emitting layer 142G includes, for example, at least one of a green light emitting material, a hole transport material, an electron transport material, or both-charges transport material. The green light emitting material may be fluorescent or phosphorescent. Specifically, the green light emitting layer 142G includes, for example, a mixture of DPVBi and 5 wt % of coumarin 6.

Note that, in a case where the organic layer 14 is configured to be able to emit white light, the configuration of the organic layer 14 is not limited to the above, and may include, for example, a configuration as illustrated in FIG. 3B. In the example of FIG. 3B, the organic layer 14 has a structure in which the hole injection layer 140, the hole transport layer 141, the blue light emitting layer 142B, an electron transport layer 146, a charge generation layer 147, a hole transport layer 148, a yellow light emitting layer 142Y, and the electron transport layer 143 are stacked. This structure is a structure including the blue light emitting layer 142B and the yellow light emitting layer 142Y as the light emitting layer 142, and is a so-called 2 stack structure. Note that, also in FIG. 3B, similarly to the case of FIG. 3A, the electron injection layer 144 may be provided between the electron transport layer 143 and the second electrode 15.

### (Second Electrode)

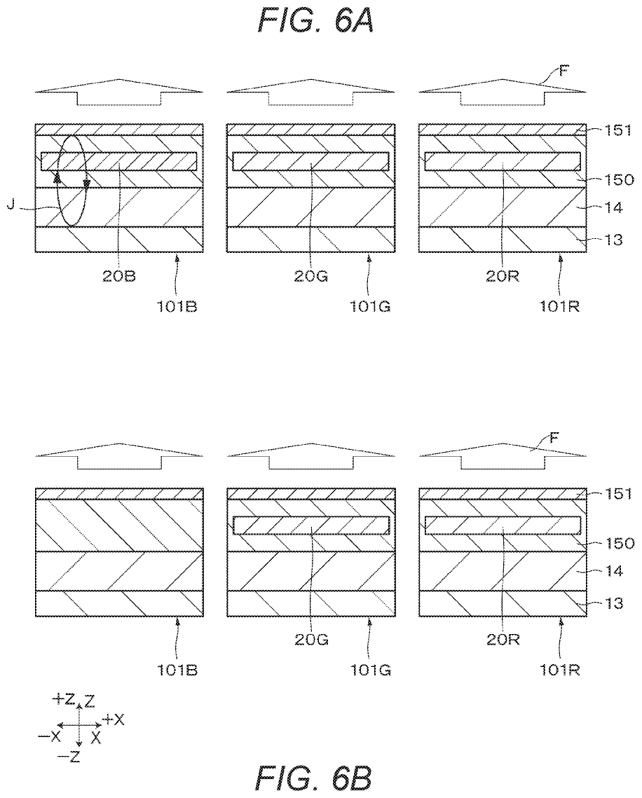

In the light emitting element 104, the second electrode 15 is provided to face the first electrode 13. The second electrode 15 is provided as an electrode common to the sub-pixels 101. The second electrode 15 is a cathode electrode. The second electrode 15 is preferably a transparent electrode having transparency to light generated in the organic layer 14. The transparent electrode herein includes a transparent electrode including the transparent conductive layer 150 and a transparent electrode including a stacked structure including the transparent conductive layer 150 and a semi-transmissive reflective layer 151. In the example of FIGS. 1, 6A, and the like, the second electrode 15 is formed in a stacked structure including the transparent conductive layer 150 and the semi-transmissive reflective layer 151. Note that the semi-transmissive reflective layer 151 may be formed separately from the second electrode 15.

The second electrode 15 includes at least one of a metal layer or a metal oxide layer. More specifically, the second electrode 15 includes a single layer film of a metal layer or a metal oxide layer, or a laminated film of a metal layer and a metal oxide layer. In a case where the second electrode 15 includes the laminated film, the metal layer may be provided on the organic layer 14 side, or the metal oxide layer may be provided on the organic layer 14 side.

As the transparent conductive layer 150, a transparent conductive material having good optical transparency and a small work function is suitably used. The transparent conductive layer 150 can include, for example, a metal oxide. Specifically, examples of a material of the transparent conductive layer 150 can include a material including at least one of a mixture of indium oxide and tin oxide (ITO), a mixture of indium oxide and zinc oxide (IZO), or zinc oxide (ZnO).

The semi-transmissive reflective layer 151 can include, for example, a metal layer. Specifically, examples of a material of the semi-transmissive reflective layer 151 can include a material including at least one metal element selected from a group including magnesium (Mg), aluminum (Al), silver (Ag), gold (Au), and copper (Cu). The metal layer may include the at least one metal element described above as a constituent element of an alloy. Specific examples of the alloy include an MgAg alloy and an AgPdCu alloy.

### (Refractive Index Adjustment Layer)

The second electrode 15 includes a refractive index adjustment layer 20. In the example of FIGS. 1, 6A, and the like, the refractive index adjustment layer 20 is included in the transparent conductive layer 150 of the second electrode 15. Furthermore, in this example, the refractive index adjustment layer 20 is arranged inside the transparent conductive layer 150 for each sub-pixel 101. For example, a refractive index adjustment layer 20B in the sub-pixel 101B, a refractive index adjustment layer 20G in the sub-pixel 101G, and a refractive index adjustment layer 20R in the sub-pixel 101R are included in the respective second electrodes 15. Note that, in a case where the refractive index adjustment layers 20R, 20G, and 20B are not distinguished from each other, the refractive index adjustment layers 20R, 20G, and 20B are collectively referred to as a refractive index adjustment layer 20.

The refractive index adjustment layer 20 includes a material having optical transparency, and preferably includes a transparent material.

Furthermore, as a material of the refractive index adjustment layer 20, a material having a quality of material and a refractive index according to a structure of the sub-pixel 101 is used. In this case, compositions of the refractive index adjustment layers 20R, 20G, and 20B in the sub-pixel 101 corresponding to the respective color types are different from each other. “Compositions are different from each other” as used herein means that they are different from each other in at least one of a quality of material, a refractive index, and a constituent ratio.

As the material of the refractive index adjustment layer 20, examples of a material having a high refractive index include materials having a refractive index of about greater than or equal to 1.9 and less than or equal to 2.4, such as Al₂O₃, SiNₓ, HfO₂, Ta₂O₅, Nb₂O₅, and TiO₂.

As the material of the refractive index adjustment layer 20, examples of a material having a low refractive index include materials having a refractive index of about greater than or equal to 1.4 and less than or equal to 1.9, such as SiO2, LiF, MgF, and SiON.

Furthermore, examples of the material of the refractive index adjustment layer 20 include various organic materials and other organic compounds used in the organic layer 14.

The transparent conductive layer 150 and the refractive index adjustment layer 20 are preferably set to have a thickness in a range of, for example, 10 nm to 500 nm in total. Note that, the thickness of the other layer is preferably set to, for example, about 100 nm to 300 nm for the first electrode 13, and about 20 to 500 nm for the organic layer 14.

### (Resonator Structure)

The resonator structure 19 is formed in the display device 10. The resonator structure 19 is a cavity structure and is a structure that causes emitted light from the organic layer 14 to resonate. In the display device 10, the resonator structure 19 is formed in the light emitting element 104, and in the example of FIGS. 1, 6A, and the like, the resonator structure 19 includes the first electrode 13, the organic layer 14, and the second electrode 15, and also includes the refractive index adjustment layer 20. Causing the emitted light from the organic layer 14 to resonate means causing light of a specific wavelength included in the emitted light to resonate.

As illustrated in FIG. 6A, in emitted light J from the organic layer 14, a component that reflects and resonates between the first electrode 13 and the second electrode (semi-transmissive reflective layer 151) is emphasized, and emphasized light is emitted from the light emitting surface side (first surface side) is emitted toward the outside (in a direction of a thick arrow F in FIG. 6). FIG. 6A is a cross-sectional view of a main part of each sub-pixel 101 of the display device of FIG. 1. In FIG. 6A and the like, the thick arrow F is a direction of the emitted light emitted from the light emitting element 104. This similarly applies to FIGS. 6B, 7 to 9, 11, and 16 to 20. In the example of the display device 10 illustrated in FIGS. 1, 6A, and the like, the organic layer 14 outputs white light as emitted light, and the resonator structure 19 causes light of a specific wavelength included in the white light to resonate. At this time, light having a predetermined wavelength in the white light from the organic layer 14 is emphasized. Then, light is emitted from the second electrode 15 side (that is, the light emitting surface side) of the light emitting element 104 toward the outside in a state where the light of the predetermined wavelength is emphasized. Note that the light of the predetermined wavelength is light corresponding to a predetermined color type, and indicates light corresponding to a color type determined according to the sub-pixel 101. In the example of FIGS. 1, 6A, and the like, the display device 10 includes the sub-pixels 101R, 101G, and 101B, and the light emitting elements 104R, 104G, and 104B according to the respective sub-pixels 101R, 101G, and 101B. Furthermore, resonator structures 19R, 19G, and 19B are formed corresponding to the light emitting elements 104R, 104G, and 104B, respectively. In the resonator structure 19R, red light out of the emitted light from the organic layer 14 resonates. Light is emitted from the second electrode 15 of the light emitting element 104R toward the outside in a state where the red light is emphasized. In the resonator structures 19G and 19B, green light and blue light of the emitted light from the organic layer 14 resonate, respectively. In the sub-pixels 101G and 101B, light is emitted from the second electrodes 15 of the light emitting elements 104G and 104B toward the outside in a state where the green light and the blue light are emphasized. Note that, in the present specification, in a case where the resonator structures 19R, 19G, and 19B are not particularly distinguished from each other, the resonator structures 19R, 19G, and 19B are collectively referred to as a resonator structure 19.

### (Optical Path Length)

Resonance of the emitted light from the organic layer 14 is formed by light reflection between the second electrode 15 and the first electrode 13. In the example of FIG. 6, as described above, the resonance of the emitted light is formed by light reflection between the semi-transmissive reflective layer 151 and the first electrode 13. An optical path length (sometimes referred to as an optical distance) between the semi-transmissive reflective layer 151 and the first electrode 13 is set according to light of a predetermined color type. The predetermined color type is a color type of light desired to be emitted by the sub-pixel 101. For example, in the resonator structure 19R formed in the sub-pixel 101R, the optical path length between the first electrode 13 and the second electrode 15 is set to generate resonance of red light. In the resonator structures 19G and 19B formed in the sub-pixels 101G and 101B, the optical path lengths between the first electrode 13 and the second electrode 15 are set to generate resonance of green light and blue light, respectively. In the example of FIGS. 1, 6, and the like, the refractive index adjustment layer 20 is provided and the resonator structure 19 is formed to satisfy a resonance condition for each sub-pixel 101.

### (Resonance Condition)

In the resonator structure 19, the resonance condition is preferably satisfied. The resonance condition indicates that the following Formula 1 is satisfied.

2L/λ+φ/2π=m (Formula 1)

In Formula 1 described above, L represents an optical distance [nm] between the first electrode 13 and the second electrode 15, λ represents a peak wavelength [nm] of a spectrum of light corresponding to a predetermined color type, φ represents a magnitude [rad] (radian) of a phase shift caused by reflection of light at the first electrode 13 and the second electrode 15, and m represents an integer (resonance order). The light corresponding to the predetermined color type corresponds to light desired to be extracted to the outside.

The optical distance L indicates a summation of products of thicknesses and refractive indexes of the respective layers formed between the first electrode 13 and the second electrode 15. Thus, the optical distance L can be adjusted by setting the refractive index of the refractive index adjustment layer 20 to a value according to the color type of the sub-pixel 101. Then, the quality of material and the thickness of the refractive index adjustment layer 20 are adjusted according to the color type of the sub-pixel 101 so that Formula 1 of the resonance condition described above is satisfied, and the thickness of each layer is adjusted. Assuming that a refractive index N1 and a thickness D1 of the refractive index adjustment layer 20B, a refractive index N2 and a thickness D2 of the refractive index adjustment layer 20G, and a refractive index N3 and a thickness D3 of the refractive index adjustment layer 20R are set, the optical distance L is adjusted according to the refractive indexes N1, N2, and N3 and the thicknesses D1, D2, and D3. Thus, the thicknesses D1, D2, and D3 can be adjusted by selecting the refractive indexes N1, N2, and N3 of the refractive index adjustment layer 20, and a difference in physical thickness (specifically, a level difference between the sub-pixels 101) between the sub-pixels 101 having different color types can be suppressed.

### (Protective Layer)

A protective layer 16 is formed on the first surface of the second electrode 15. The protective layer 16 shields the light emitting elements 104 from the outside air, and suppress moisture infiltration into the light emitting elements 104 from the external environment. Furthermore, in a case where the semi-transmissive reflective layer 151 of the second electrode 15 includes a metal layer, the protective layer 16 may have a function of suppressing oxidation of the metal layer.

The protective layer 16 includes an insulating material. As the insulating material, for example, thermosetting resin or the like can be used. In addition, the insulating material may be SiO, SiON, AIO, TiO, or the like. In this case, examples of the protective layer 16 include a CVD film including SiO, SiON, or the like, an ALD film including AlO, TiO, SiO, or the like, and the like. The protective layer 16 may be formed as a single layer or may be formed in a state where a plurality of layers is stacked. Note that the CVD film indicates a film formed using chemical vapor deposition. The ALD film indicates a film formed using atomic layer deposition.

### (Filling Resin Layer)

The filling resin layer 17 may be formed on the first surface side of the protective layer 16. The filling resin layer 17 can exert a function of smoothing the surface of the first surface to be a formation surface of the protective layer 16. Furthermore, the filling resin layer 17 can have a function as an adhesive layer for bonding the counter substrate 18 to be described later. Examples of the filling resin layer 17 include ultraviolet curable resin, thermosetting resin, and the like.

### (Counter Substrate)

The counter substrate 18 is provided on the filling resin layer 17 in a state of facing the drive substrate 11. The counter substrate 18 seals the light emitting elements 104 together with the filling resin layer 17. The counter substrate 18 may include a similar material to the substrate 11A included in the drive substrate 11, and preferably includes a material such as glass or the like.

### [1-2 Function and Effect]

In the display device having the resonator structure 19, for example, a distance between the second electrode 15 and the organic layer 14 has been adjusted according to the color type of the sub-pixel 101 so that the optical distance L satisfies the resonance condition for each sub-pixel 101. Furthermore, in the resonator structure 19, as another adjustment method for satisfying the resonance condition, it has been performed to separately arrange a reflector on the second surface side of the first electrode 13 and adjust a distance between the reflector and the second electrode 15. In any of these cases, since the thickness of each layer is adjusted so that the optical distance satisfies the resonance condition in the sub-pixels 101 of the respective color types, there has been a case where a large level difference (level difference on the first surface side between the sub-pixels 101) is generated between the sub-pixels 101 of adjacent different color types. Thus, in the display device, reduction of such a level difference has been required from the viewpoint of color purity and effective use of light.

According to the present disclosure, the second electrode 15 includes the refractive index adjustment layer 20. Since the refractive index adjustment layer 20 is formed according to the color type of the sub-pixel 101, the optical distance L can be adjusted for each sub-pixel 101 by the refractive index adjustment layer 20. That is, by arranging the refractive index adjustment layer 20 having a predetermined refractive index or the like according to the color type of the sub-pixel 101, it is possible to reduce the level difference on the first surface side of the light emitting element 104 between the adjacent sub-pixels 101. Furthermore, since the optical distance L can be adjusted by the refractive index of the refractive index adjustment layer 20, the thickness of the display device 10 can be suppressed not to be thicker than necessary, and a decrease in light extraction efficiency can also be suppressed.

### [1-3 Method of Manufacturing Display Device]

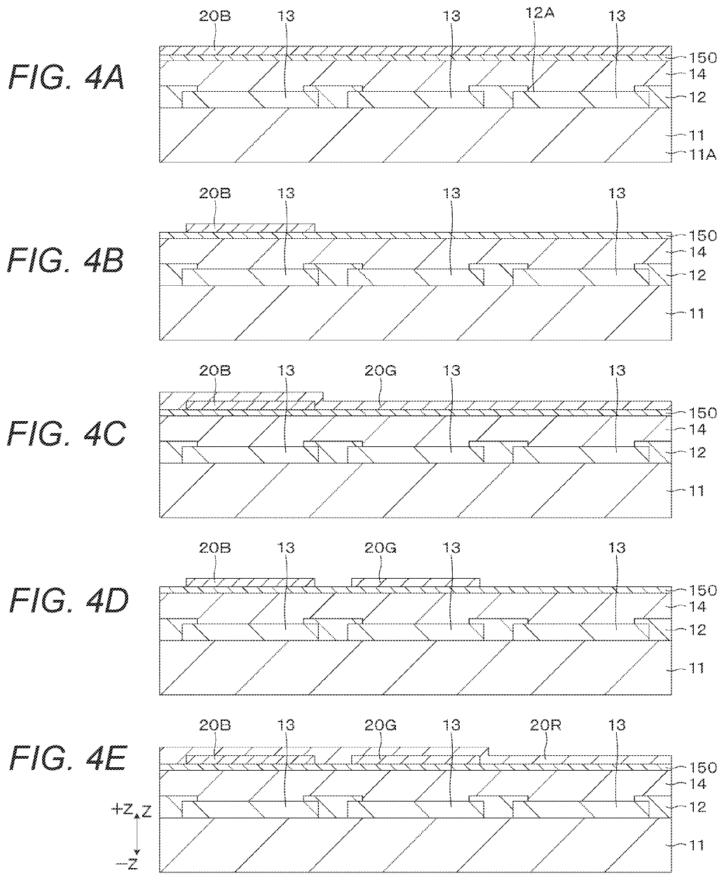

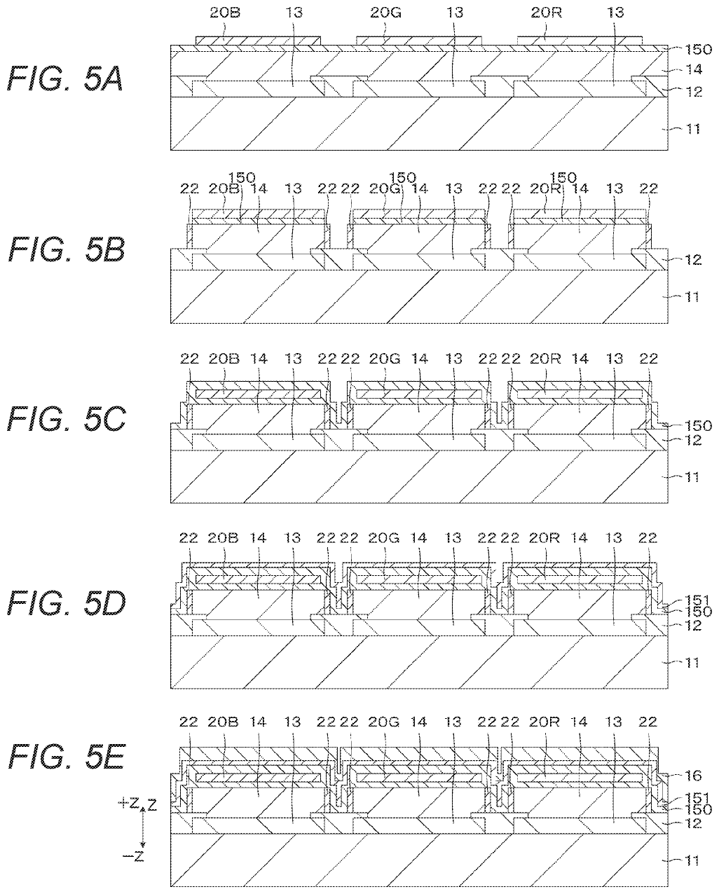

Next, an example of a method of manufacturing the display device 10 will be described in detail with reference to FIGS. 4A to 4E and FIGS. 5A to 5E. Note that the description will be continued by taking, as an example, a case where the emission color of the organic layer 14 is white regardless of the color type of the sub-pixel 101.

The drive substrate 11 is formed by forming transistors and various wiring lines on the substrate 11A including a semiconductor material such as silicon.

On the drive substrate 11, for example, the first electrode 13 is patterned by sputtering a material such as an Al alloy according to a pattern of the first electrode 13. Next, the insulating layer 12 is formed between the adjacent first electrodes 13. That is, for example, the insulating layer 12 is patterned on the entire surface including the first electrode 13 by using a patterning technique such as lithography or etching. Furthermore, at this time, the openings 12A are formed to expose the upper surfaces of first electrodes 13.

The hole injection layer 140, the hole transport layer 141, the red light emitting layer 142R, the light emission separation layer 145, the blue light emitting layer 142B, the green light emitting layer 142G, the electron transport layer 143, and the like are sequentially formed on the first electrode 13. For the formation of these layers, for example, a vapor deposition method or the like is used. Moreover, the transparent conductive layer 150 (for example, IZO) of the second electrode 15 is formed by using a sputtering method or the like.

Next, the refractive index adjustment layer 20B is formed on the transparent conductive layer 150 (FIG. 4A). Moreover, the refractive index adjustment layer 20B is formed in a portion corresponding to the sub-pixel 101B. This can be implemented by processing the refractive index adjustment layer 20B formed by appropriately using a method such as a CVD method, an ALD method, or a sputtering method by a dry etching method (FIG. 4B).

Similarly to the formation of the refractive index adjustment layer 20B, the refractive index adjustment layer 20G is formed (FIG. 4C), and processing is performed by a dry etching method to leave a portion corresponding to the sub-pixel 101G (FIG. 4D). Moreover, the refractive index adjustment layer 20R is formed (FIG. 4E), and processing is performed by a dry etching method to leave a portion corresponding to the sub-pixel 101G (FIG. 5A). In this way, the refractive index adjustment layers 20G and 20R are also formed in the portions corresponding to the sub-pixels 101G and 101R.

Next, the transparent conductive layer 150 and the organic layer 14 are subjected to division processing for each sub-pixel 101 according to an arrangement pattern of the sub-pixels 101. For the division processing, for example, a dry etching method is used. Then, a side wall layer 22 is formed on side end surfaces of the transparent conductive layer 150 and the organic layer 14 (FIG. 5B). The side wall layer 22 may be formed by, for example, deposition or the like at the time of division processing (regeneration product at the time of etching). Since the side wall layer 22 is formed, light is less likely to leak to the adjacent sub-pixel even if emitted light in an oblique direction is generated.

Then, the transparent conductive layer 150 of the second electrode 15 is further formed by appropriately using a sputtering method or the like (FIG. 5C). At this time, the refractive index adjustment layer 20 is included in the transparent conductive layer 150. Moreover, the semi-transmissive reflective layer 151 is formed on the transparent conductive layer 150 (FIG. 5D). This can be implemented, for example, by sputtering a material of the semi-transmissive reflective layer 151 such as an Ag alloy on the transparent conductive layer 150. The second electrode 15 can function as a common cathode electrode common to the sub-pixels 101.

The protective layer 16 is formed to cover the second electrode 15 (FIG. 5E). The formation of the protective layer 16 can be specifically implemented, for example, by forming a material such as SiN on the entire surface by a CVD method.

Then, the counter substrate 18 is bonded to the first surface side of the protective layer 16. At this time, an adhesive resin for bonding the counter substrate 18 and the protective layer 16 together serves as the filling resin layer 17. In this way, the display device 10 is obtained.

### [1-4 Modifications]

Next, modifications of the display device 10 according to the first embodiment will be described.

### (Modification 1)

In the display device 10 according to the first embodiment, as illustrated in FIG. 6B, arrangement of the refractive index adjustment layer 20 may be avoided for at least the sub-pixel 101 corresponding to one color type among the sub-pixels 101 (Modification 1). FIG. 6B is a cross-sectional view illustrating a main part of an implementation example of the display device 10 according to Modification 1 of the first embodiment.

In the example illustrated in FIG. 6B, in at least the sub-pixel 101 corresponding to one color type different from the color type of the sub-pixel 101 in which the refractive index adjustment layer 20 is arranged, the arrangement of the refractive index adjustment layer 20 is avoided. That is, the refractive index adjustment layer 20 is not arranged for the sub-pixel 101B, and the refractive index adjustment layers 20G and 20R are formed for the sub-pixels 101G and 101R of other color types. In this case, the configuration is simplified, the number of manufacturing steps can be reduced, and ease of manufacturing is improved. Note that, from this viewpoint, the refractive index adjustment layer 20 may be formed in only one of the sub-pixels 101B, 101G, or 101R (not illustrated).

### (Modification 2)

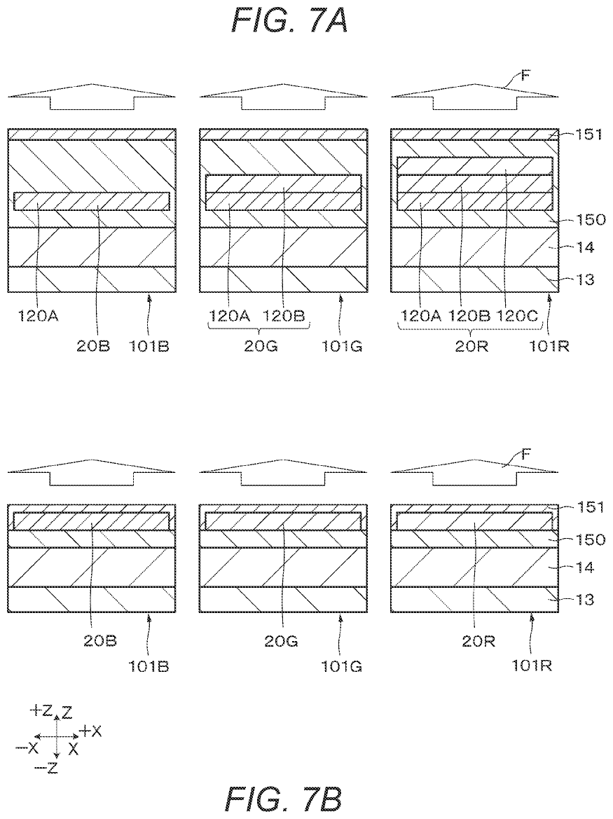

In the display device 10 according to the first embodiment, as illustrated in FIG. 7A, the refractive index adjustment layer 20 may have a multilayer structure for at least the sub-pixel 101 corresponding to one color type among the sub-pixels 101 (Modification 2). FIG. 7A illustrates an implementation example of the display device 10 according to Modification 2 of the first embodiment.

In the example illustrated in FIG. 7A, the refractive index adjustment layers 20G and 20R have a multilayer structure. The refractive index adjustment layer 20B of the sub-pixel 101B has a single layer structure, and the refractive index adjustment layers 20G and 20R are formed in a two-layer stacked structure and a three-layer stacked structure, respectively. Furthermore, in this example, a first layer 120A included in the refractive index adjustment layer 20B is also included in the refractive index adjustment layers 20G and 20R, and the refractive index adjustment layer 20G and the refractive index adjustment layer 20R include the first layer 120A and a second layer 120B. The refractive index adjustment layer 20R further includes a third layer 120C. The first layer 120A, the second layer 120B, and the third layer 120C are layers each including a material that can be used as a material included in the refractive index adjustment layer 20. In the case of FIG. 7A, the quality of material, the refractive index, and the thickness of the first layer 120A, the second layer 120B, and the third layer 120C are selected so that the resonance condition according to the color type of the sub-pixel 101 is satisfied in the resonator structure 19 of each sub-pixel 101. According to the display device 10 of Modification 2, the degree of freedom in design is improved by an increase in the number of stacked layers.

### (Modification 3)

In the display device 10 according to the first embodiment, as illustrated in FIG. 7B, the refractive index adjustment layer 20 may be formed between the transparent conductive layer 150 and the semi-transmissive reflective layer 151 (Modification 3). FIG. 7B illustrates an implementation example of the display device 10 according to Modification 1 of the first embodiment.

In the example of FIG. 7B, the semi-transmissive reflective layer 151 covers all the refractive index adjustment layers 20B, 20G, and 20R formed on the transparent conductive layer 150. In this case, a step of further forming the transparent conductive layer 150 on the refractive index adjustment layers 20B, 20G, and 20R formed on the transparent conductive layer 150 (step illustrated in FIG. 5C) can be omitted, so that the number of steps can be reduced.

### (Modification 4)

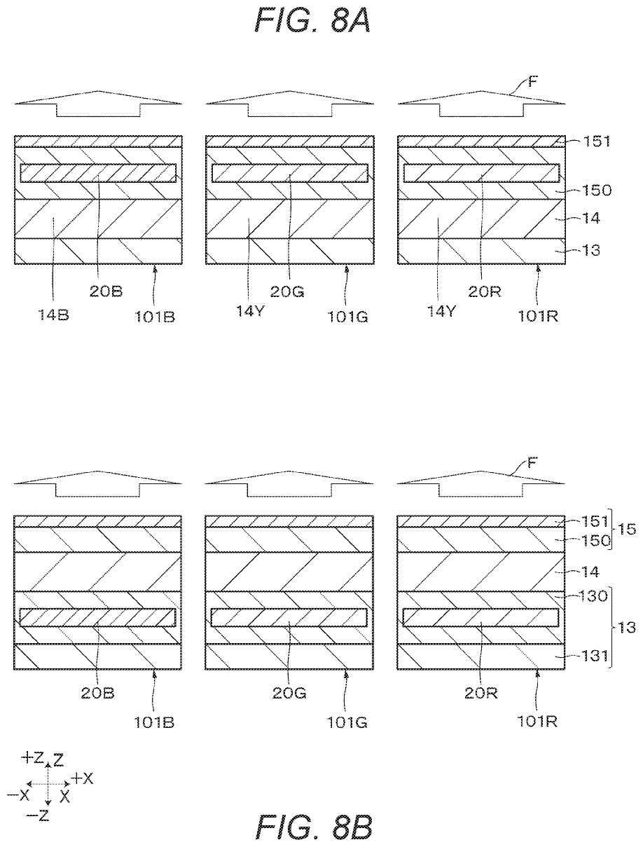

In the example of the display device 10 according to the first embodiment, the organic layers 14 provided in the sub-pixels 101B, 101G, and 101R all have the same emission color of white, but a combination of the organic layers 14 is not limited thereto. In the display device 10 according to the first embodiment, as illustrated in FIG. 8A, an emission color (first emission color) of the organic layer 14 provided in at least the sub-pixel 101 corresponding to one color type may be a color type different from an emission color (second emission color) of the organic layer 14 provided in the sub-pixels 101 corresponding to a plurality of other color types.

In the example of FIG. 8A, the organic layer 14 provided in the sub-pixel 101B is an organic layer 14B having blue as the first emission color. In this example, for the sub-pixel 101B, the refractive index adjustment layer 20B is included in the second electrode 15 (transparent conductive layer 150), and the resonator structure 19 is formed, but the present embodiment is not limited thereto, and the refractive index adjustment layer 20B may be omitted.

In the display device 10 according to Modification 4, the second emission color of the organic layer 14 provided in the sub-pixels 101 corresponding to the plurality of other color types is common among the sub-pixels 101 corresponding to the plurality of other color types. In the example of FIG. 8A, the organic layer 14 provided in the sub-pixels 101G and 101R is an organic layer 14Y having yellow as the second emission color. The organic layer 14 having yellow as an emission color may have a structure in which a red light emitting layer and a green light emitting layer are stacked. Furthermore, in the sub-pixels 101G and 101R, the refractive index adjustment layers 20G and 20R are included in the second electrode 15 (transparent conductive layer 150). In the refractive index adjustment layers 20G and 20R, mutually different refractive indexes and thicknesses are determined so that the resonator structures 19G and 19R formed in the sub-pixels 101G and 101R cause green and red light to resonate, respectively.

According to the display device 10 of Modification 4, high luminous efficiency can be achieved for a predetermined color (blue in the example of FIG. 8A). Furthermore, for other colors (red and green in the example of FIG. 8A), by providing the different refractive index adjustment layers 20 according to the sub-pixels 101, it is possible to efficiently extract light of a color type according to the sub-pixel 101.

### (Modification 5)

In the display device 10 according to the first embodiment, as illustrated in FIG. 8B, the refractive index adjustment layer 20 may be included in the first electrode 13 (Modification 5). FIG. 8B illustrates an implementation example of the display device 10 according to Modification 5 of the first embodiment.

In the example of FIG. 8B, the first electrode 13 is an anode electrode including the transparent conductive layer 130 and a reflective layer 131, and the transparent conductive layer 130 is arranged closer to the organic layer 14. A metal such as Al is suitably used for the reflective layer 131. Furthermore, as the transparent conductive layer 130, a metal oxide film such as ITO or IZO is suitably used.

In the display device 10 according to Modification 5, the refractive index adjustment layer 20 is included in the transparent conductive layer 130. Various conditions such as the refractive index, the quality of material, and the thickness of the refractive index adjustment layer 20 are similar to those in a case where the refractive index adjustment layer 20 is included in the second electrode 15. That is, also in a case where the refractive index adjustment layer 20 is included in the first electrode 13, conditions such as the refractive index, the quality of material, and the thickness of the refractive index adjustment layer 20 are preferably determined on the basis of the optical distance L at which the resonance condition is satisfied in the resonator structures 19B, 19G, and 19R in the respective sub-pixels 101B, 101G, and 101R.

Note that, in the case of Modification 5, the second electrode 15 includes the transparent conductive layer 150 and the semi-transmissive reflective layer 151 in FIG. 8B, but the present embodiment is not limited thereto, and the second electrode 15 may include the semi-transmissive reflective layer 151. In a case where the second electrode 15 includes the semi-transmissive reflective layer 151, the second electrode 15 preferably includes a material having good optical transparency and a small work function. For example, the second electrode 15 includes a metal layer of magnesium (Mg), silver (Ag), an alloy thereof, or the like. Furthermore, the second electrode 15 may include the semi-transmissive reflective layer 151 as a multilayer. In this case, the second electrode 15 may include, for example, a stacked structure of metal layers such as of calcium (Ca), barium (Ba), lithium (Li), cesium (Cs), indium (In), magnesium (Mg), and of silver (Ag) as a first layer, and magnesium (Mg), silver (Ag), or an alloy thereof as a second layer. Note that, in a case where second electrode 15 includes the semi-transmissive reflective layer 151, the semi-transmissive reflective layer 151 included in the second electrode 15 is preferably set in a range of 3 to 20 nm.

Also in a case where the refractive index adjustment layer 20 is included in the first electrode 13 as in the display device 10 according to Modification 5, an effect of reducing the level difference between the sub-pixels 101 can be obtained similarly to a case where the refractive index adjustment layer 20 is included in the second electrode 15.

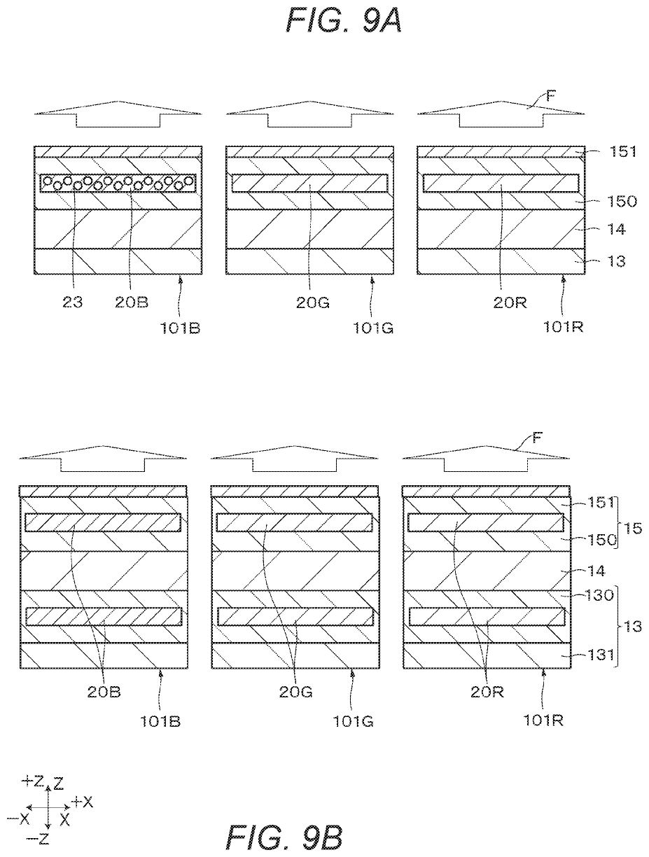

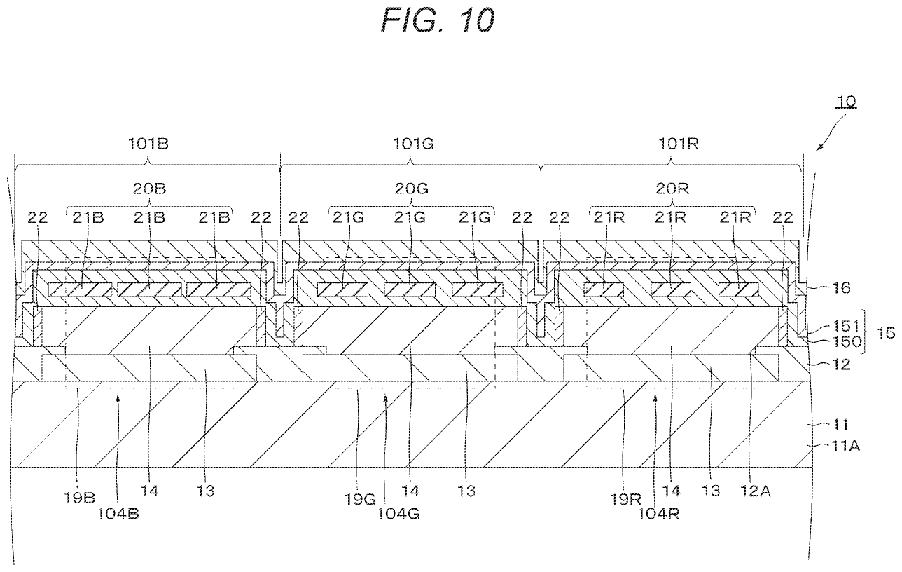

Note that, in the display device 10 according to the first embodiment, the display device 10 has been described with a case where the refractive index adjustment layer 20 is formed in the second electrode 15 as an example, and in Modification 5, a case has been described where the refractive index adjustment layer 20 is included in the first electrode. The display device 10 according to the first embodiment is not limited thereto, and both the refractive index adjustment layer 20 included in the first electrode 13 and the refractive index adjustment layer 20 included in the second electrode 15 may be provided (FIG. 9B). Also in this case, similarly to the case where the refractive index adjustment layer 20 is included in the first electrode 13 or the case where the refractive index adjustment layer 20 is included in the second electrode 15, the effect of reducing the level difference between the sub-pixels 101 can be obtained.

### (Modification 6)

In the display device 10 according to the first embodiment, as illustrated in FIG. 9A, in a case where the second electrode 15 includes the transparent conductive layer 150 and the refractive index adjustment layer 20 is provided in the transparent conductive layer 150, the refractive index adjustment layer 20 may have a density reduction structure (Modification 6). FIG. 9A illustrates an implementation example of the display device 10 according to Modification 1 of the first embodiment.

In the example of FIG. 9A. The refractive index adjustment layer 20 is included in the transparent conductive layer 150. Then, the refractive index adjustment layer 20 provided in the sub-pixel 101B has a density reduction structure 23.

As illustrated in the example of FIG. 9A, examples of the density reduction structure 23 can include, for example, a porous structure. The refractive index adjustment layer 20 has the density reduction structure 23, thereby being a layer in a sparse state (layer with low density), and the refractive index can be lowered. For example, by forming a film (silicon oxide film or the like) using SiOx into a porous film to form the refractive index adjustment layer 20, the refractive index adjustment layer 20 can be a layer having a refractive index reduced to less than or equal to 1.4. In this case, the optical distance can be adjusted to be short. For this reason, by forming the density reduction structure 23 in the refractive index adjustment layer 20 for the sub-pixel 101 having a short optical distance satisfying the resonance condition, it is possible to more effectively reduce the level difference between the sub-pixels 101. As described above, by forming the density reduction structure 23 in the refractive index adjustment layer 20, the degree of freedom in design can be improved.

Note that the display device 10 according to Modification 6 can be similarly applied to a case where the first electrode 13 includes the transparent conductive layer 130. That is, in a case where the refractive index adjustment layer 20 is provided in the transparent conductive layer 130, the refractive index adjustment layer 20 may have the density reduction structure 23.

### 2. Second Embodiment

### [2-1 Configuration of Display Device]

In the description of the display device 10 according to the first embodiment described above, a case has been taken as an example where the refractive index adjustment layer 20 is formed as a layer spreading in one surface in a surface direction of the light emitting surface (a surface direction of the formation surface of the display region 10A). The refractive index adjustment layer 20 in the display device 10 according to the first embodiment is not limited thereto, and as illustrated in FIG. 10, the refractive index adjustment layer 20 may include a plurality of optical adjustment layers 21 (second embodiment). FIG. 10 is a cross-sectional view illustrating an implementation example of a display device 10 according to the second embodiment. As illustrated in FIG. 10, a plurality of optical adjustment layers 21B, a plurality of optical adjustment layers 21G, and a plurality of optical adjustment layers 21R is provided for the respective refractive index adjustment layers 20B, 20G, and 20R. Note that, in a case where the optical adjustment layers 21B, 21G, and 21R are not particularly distinguished from each other, the optical adjustment layers 21B, 21G, and 21R are collectively referred to as an optical adjustment layer 21.

### (Optical Adjustment Layer)

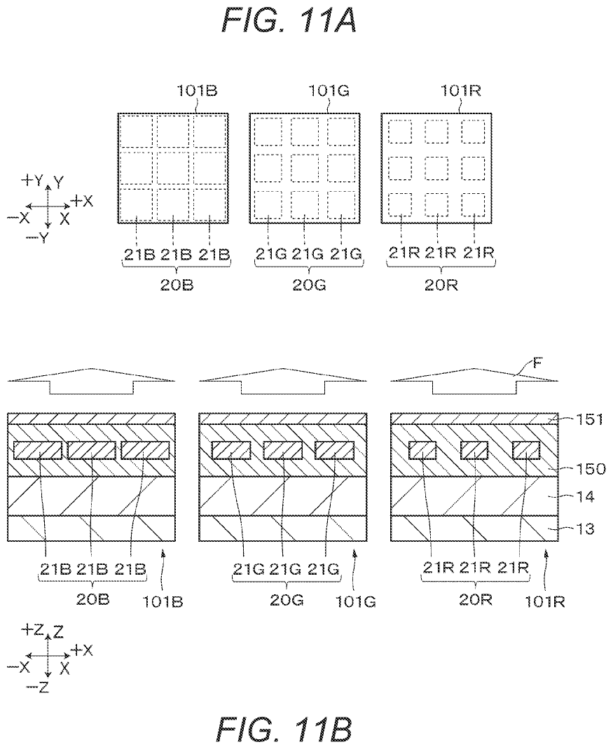

The optical adjustment layer 21 is a constituent unit serving as a unit layer of the refractive index adjustment layer 20. In the display device 10, as illustrated in FIG. 11A, for each sub-pixel 101, the plurality of optical adjustment layers 21 is arranged in a state of being separated from each other along a light emitting surface direction of the light emitting element 104 (a spreading direction of the formation surface of the display region 10A (a direction along the XY plane)). In the example of FIG. 11A, the optical adjustment layers 21B, 21G, and 21R are arranged in a lattice pattern with a predetermined size and pitch in the respective sub-pixels 101B, 101G, and 101R. Then, in this case, the refractive index adjustment layer 20 is formed in a group structure of the optical adjustment layers 21 arranged in a lattice pattern.

In the example of FIG. 10, as also illustrated in FIG. 11B, the second electrode 15 includes the transparent conductive layer 150 and the semi-transmissive reflective layer 151, and the plurality of optical adjustment layers 21 is included in the transparent conductive layer 150. Furthermore, for each of the optical adjustment layers 21B, 21G, and 21R, a refractive index of the plurality of optical adjustment layers 21 and a refractive index of the transparent conductive layer 150 are different from each other. FIG. 11B is a cross-sectional view illustrating a main part of FIG. 10.

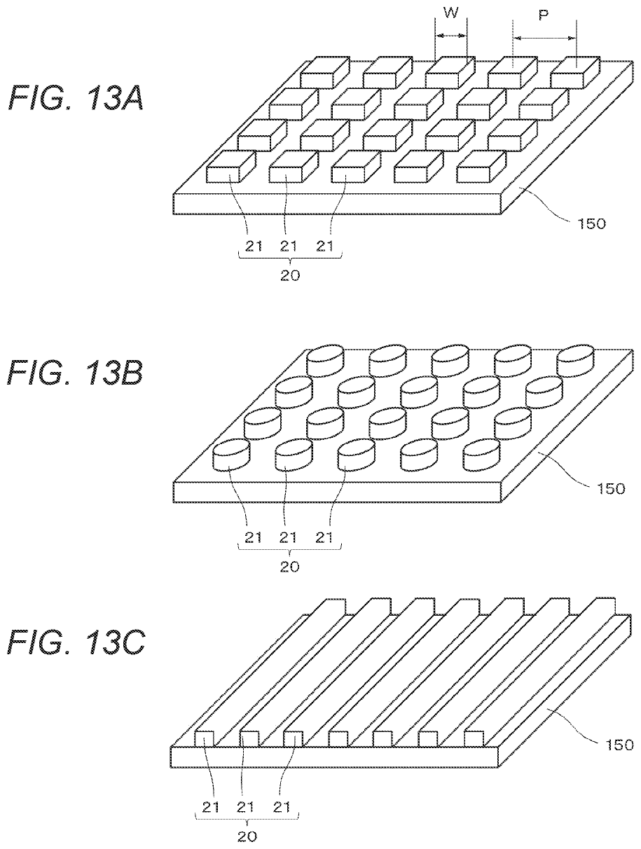

In the sub-pixel 101 corresponding to each color type, the size (indicated by a reference sign W in FIG. 13) of the plurality of optical adjustment layers 21 is preferably set to a value less than or equal to the peak wavelength of the light corresponding to the color type of the sub-pixel 101, and more preferably less than or equal to ½ of the peak wavelength.

In the sub-pixel 101 corresponding to each color type, the pitch (indicated by a reference sign P in FIG. 13) of the plurality of optical adjustment layers 21 is preferably set to a value less than or equal to the peak wavelength of the light corresponding to the color type of the sub-pixel 101, and more preferably less than or equal to ½ of the peak wavelength. For example, in the sub-pixel 101B, the pitch of the optical adjustment layers 21 is preferably a value less than or equal to the peak wavelength of the blue light, in the sub-pixel 101G, the pitch of the optical adjustment layers 21 is preferably a value less than or equal to the peak wavelength of the green light, and in the sub-pixel 101R, the pitch of the optical adjustment layers 21 is preferably a value less than or equal to the peak wavelength of the red light. Note that the pitch is determined by a center-to-center distance between adjacent optical adjustment layers 21. Furthermore, at this time, the size of the optical adjustment layer 21 is also set to a value less than or equal to the peak wavelength of light corresponding to the color type of the sub-pixel 101. In this case, effective refractive indexes neff of the refractive index adjustment layers 20 are different from each other between the sub-pixels 101 of different color types.

The effective refractive index neff is set by a volume ratio between the transparent conductive layer 150 and the optical adjustment layer 21. The volume ratio can be specified by a ratio of a volume of the optical adjustment layer 21 to an appearance volume of the transparent conductive layer 150.

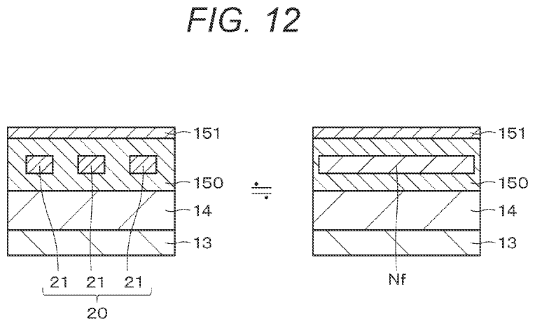

In the sub-pixel 101, in a case where the refractive index of the optical adjustment layer 21 is N1 and the refractive index of the transparent conductive layer 150 of the second electrode 15 is NO, the effective refractive index neff takes a value between the refractive index N1 and the refractive index NO according to the volume ratio between the optical adjustment layer 21 and the transparent conductive layer 150. That is, as illustrated in FIG. 12, the refractive index adjustment layer 20 includes the plurality of optical adjustment layers 21, whereby the refractive index adjustment layer 20 is a layer equivalent to a refractive index adjustment layer Nf having a value of the effective refractive index neff as the refractive index from a viewpoint of the refractive index. Note that the refractive index adjustment layer Nf is a continuous layer having the effective refractive index neff as the refractive index. In FIG. 12, a mathematical symbol indicating approximation indicates that the refractive index adjustment layer 20 and the refractive index adjustment layer Nf are equivalent to each other.

As a material of the optical adjustment layer 21, a similar material to the material of the refractive index adjustment layer 20 described in the first embodiment may be adopted.

The refractive index of the optical adjustment layer 21 is not particularly limited, and may be larger than, equal to, or smaller than a refractive index of a layer including the optical adjustment layer 21. However, from a viewpoint of making it possible to adjust the effective refractive index in a wider range, the refractive index of the optical adjustment layer 21 is preferably larger than the refractive index of the layer including the optical adjustment layer 21. For example, in a case where the second electrode 15 includes the transparent conductive layer 150 and the optical adjustment layer 21 is included in the transparent conductive layer 150, the refractive index of the optical adjustment layer 21 is preferably larger than the refractive index of the transparent conductive layer 150.

A three-dimensional shape of the optical adjustment layer 21 is not particularly limited, and may be a prismatic shape (FIG. 13A) or a cylindrical shape (FIG. 13B). Furthermore, as illustrated in FIG. 13C, the optical adjustment layer 21 may have a continuous shape in one direction. Note that FIGS. 13A to 13C each illustrate a state in which the optical adjustment layer 21 is formed on the transparent conductive layer 150, but this is a description for convenience, and in the display device 10, the upper surface side of the optical adjustment layer 21 is covered with the transparent conductive layer 150 or the semi-transmissive reflective layer 151.

The pitch P of the optical adjustment layers 21 may be changed to a value different from that in a central region of the sub-pixel 101 in a region near the peripheral edge of the sub-pixel 101. As a result, it is possible to adjust an optical influence at the peripheral edge of the sub-pixel or the boundary with the adjacent sub-pixel.

Note that, in the display device 10, the configuration other than that the refractive index adjustment layer 20 includes the plurality of optical adjustment layers 21 may be similar to that in the first embodiment.

### [2-2 Function and Effect]

In the display device 10 according to the second embodiment, the second electrode 15 includes the refractive index adjustment layer 20. Then, the refractive index adjustment layer 20 includes the plurality of optical adjustment layers 21 according to the color type of the sub-pixel 101. For this reason, the effective refractive index can be adjusted for each sub-pixel 101 by the refractive index adjustment layer 20, and the optical distance L can be adjusted. Thus, in the display device according to the second embodiment, similarly to the first embodiment, the plurality of optical adjustment layers 21 is formed having a predetermined pitch and size, whereby the level difference on the first surface side of the light emitting element 104 can be reduced between the adjacent sub-pixels 101.

Furthermore, in the display device 10 according to the second embodiment, the refractive index can be adjusted (the effective refractive index neff can be adjusted) according to the color type of the sub-pixel 101 by changing a layout pattern of the optical adjustment layers 21 without changing the quality of material of the refractive index adjustment layer 20 for each color type of the sub-pixel 101, so that the number of manufacturing steps can be easily reduced as described later.

### [2-3 Method of Manufacturing Display Device]

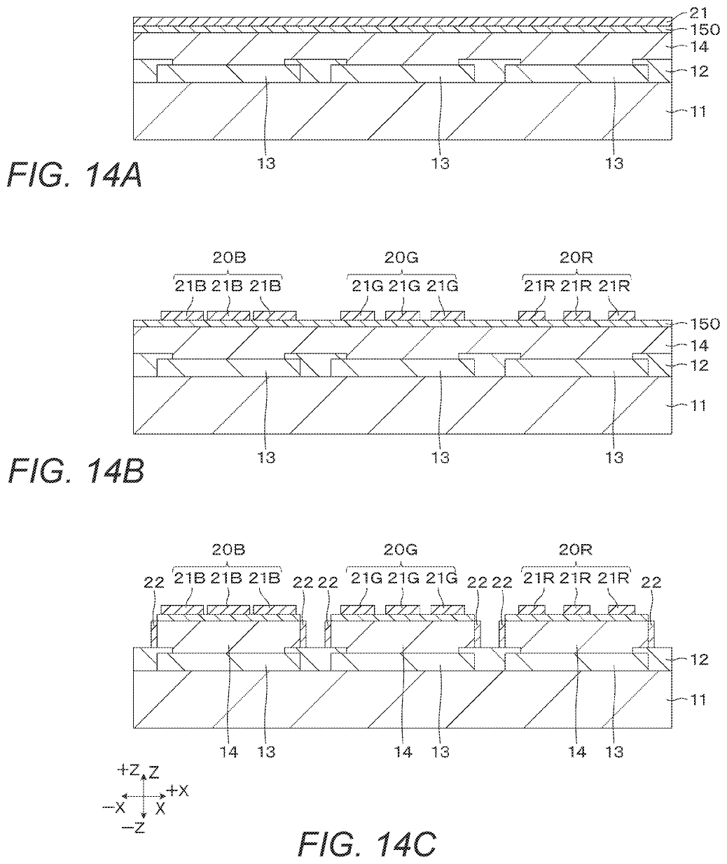

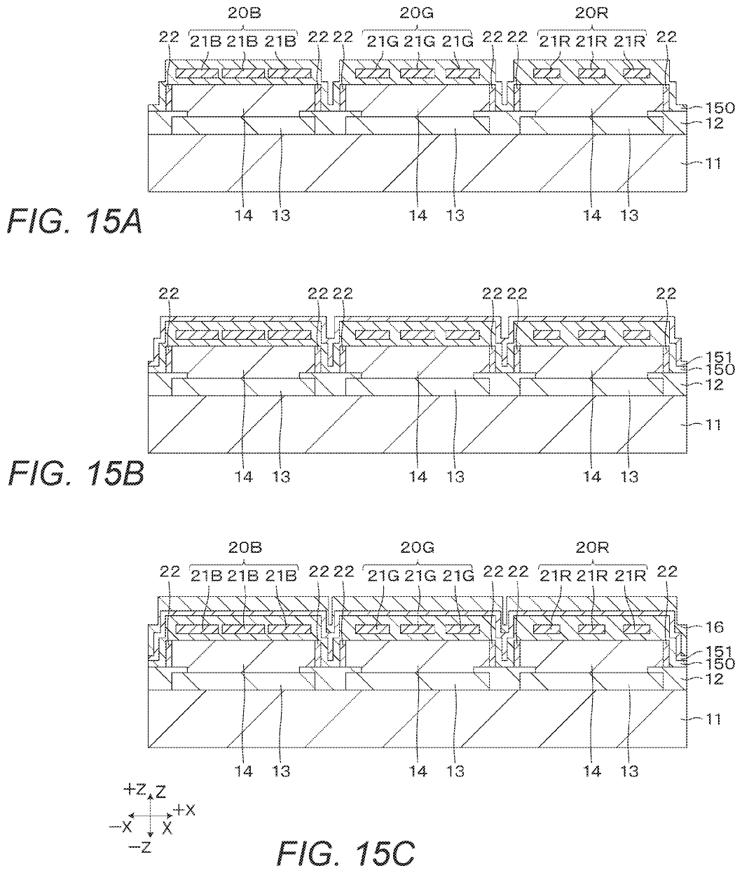

Next, an example of a method of manufacturing the display device 10 according to the second embodiment will be described in detail with reference to FIGS. 14A to 14C and FIGS. 15A to 15C.

The first electrode 13 and the organic layer 14 are formed on the drive substrate 11 similarly to the first embodiment. Moreover, the transparent conductive layer 150 of the second electrode 15 is formed similarly to the first embodiment.

The optical adjustment layer 21 is formed on the entire surface of the transparent conductive layer 150 by using a method, for example, a CVD method, an ALD method, a sputtering method, or the like (FIG. 14A). Moreover, the optical adjustment layer 21 is collectively subjected to division processing (FIG. 14B). The division processing can be implemented by, for example, a dry etching method. At this time, the plurality of optical adjustment layers 21 is formed with a pitch and a size according to the color type of each sub-pixel 101, and in a region corresponding to the sub-pixel 101B, the optical adjustment layers 21B are formed. In a region corresponding to the sub-pixel 101G, the optical adjustment layers 21G are formed. In a region corresponding to the sub-pixel 101R, the optical adjustment layers 21R are formed. As a result, the refractive index adjustment layer 20 (20B, 20G, 20R) including the plurality of optical adjustment layers 21 is formed for each sub-pixel 101.

Then, similarly to the first embodiment, the transparent conductive layer 150 and the organic layer 14 are subjected to division processing for each sub-pixel 101 by using a dry etching method or the like. Moreover, the side wall layer 22 is formed on the side end surface of the organic layer 14 (FIG. 14C). The side wall layer 22 may include, for example, a regeneration product (deposition) or the like at the time of division processing.

The transparent conductive layer 150 of the second electrode 15 is further formed by appropriately using a sputtering method or the like (FIG. 15A). At this time, a state is formed in which the optical adjustment layers 21 are included in the transparent conductive layer 150, that is, a state is formed in which the refractive index adjustment layer 20 is included in the transparent conductive layer 150. Moreover, similarly to the first embodiment, the semi-transmissive reflective layer 151 is formed on the transparent conductive layer 150 (FIG. 15B). Furthermore, the protective layer 16 is formed to cover the second electrode 15 (FIG. 15C). Then, similarly to the first embodiment, the counter substrate 18 is attached to the first surface side of the protective layer 16 with the filling resin layer 17 interposed therebetween (not illustrated). As a result, the display device 10 is obtained.

In the method of manufacturing the display device 10 described above, since the refractive index adjustment layers 20 can be collectively formed even if there is the plurality of color types of the sub-pixel 101, the number of steps can be easily reduced.

### [2-4 Modifications]

Next, modifications of the display device 10 according to the second embodiment will be described.

### (Modification 1)

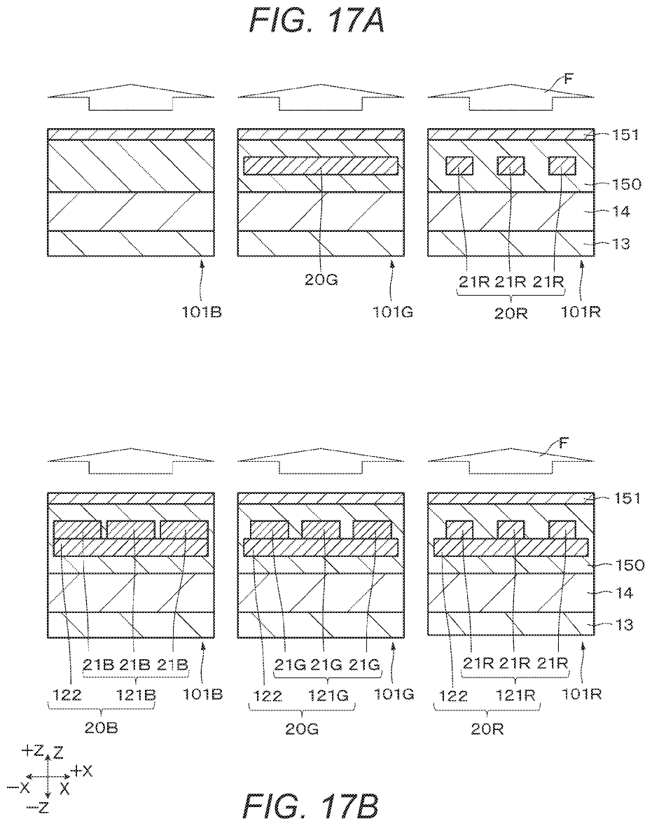

In the display device 10 according to the second embodiment, as illustrated in FIG. 17A, arrangement of the optical adjustment layer 21 may be avoided for at least the sub-pixel 101 corresponding to one color type among the sub-pixels 101 (Modification 1). FIG. 17A illustrates an implementation example of the display device 10 according to Modification 1 of the second embodiment.

In Modification 1, in at least the sub-pixel 101 corresponding to one color type different from the color type of the sub-pixel 101 in which the refractive index adjustment layer 20 is arranged, the arrangement of the refractive index adjustment layer 20 is avoided. In the example of FIG. 17A, in the sub-pixel 101B, formation of the refractive index adjustment layer 20 is avoided, that is, the arrangement of the optical adjustment layers 21 is avoided. For the sub-pixels 101G and 101R, the refractive index adjustment layers 20G and 20R are formed.

Note that, in a case where the refractive index adjustment layer 20 is formed for the plurality of sub-pixels 101, the refractive index adjustment layer 20 may include the optical adjustment layers 21 for some of the sub-pixels 101. In the example of FIG. 17A, in the sub-pixel 101G, the refractive index adjustment layer 20G including one surface layer is arranged without including the optical adjustment layers 21 as described in the first embodiment, and in the sub-pixel 101R, the refractive index adjustment layer 20R includes the optical adjustment layers 21 as described in the second embodiment.

According to Modification 1, the configuration of the display device 10 is simplified as compared with the example described in the second embodiment, whereby the number of steps is reduced and manufacturing is facilitated. Furthermore, the degree of freedom in designing the display device 10 is improved.

### (Modification 2)

In the display device 10 according to the second embodiment, as illustrated in FIG. 17B, in a case where the refractive index adjustment layer 20 has a multilayer structure, at least one layer included in the refractive index adjustment layer 20 may include the plurality of optical adjustment layers 21 (Modification 2). FIG. 17B illustrates an implementation example of the display device 10 according to Modification 2 of the second embodiment.

In the example of FIG. 17B, the refractive index adjustment layers 20B, 20G, and 20R are formed for the sub-pixels 101B, 101G, and 101R, respectively, and are all formed in a multilayer. Then, for each of the refractive index adjustment layers 20B, 20G, and 20R, at least one layer includes the plurality of optical adjustment layers 21. In the example of FIG. 17B, all of the refractive index adjustment layers 20B, 20G, and 20R are stacked in two layers of upper and lower layers, and a first layer 122 arranged at a position closer to the organic layer 14 is a layer formed in one surface. In the sub-pixel 101B, the plurality of optical adjustment layers 21B is stacked on the first surface side of the first layer 122 to form a second layer 121B. In the sub-pixel 101G, the plurality of optical adjustment layers 21G is stacked on the first surface side of the first layer 122 to form a second layer 121G. In the sub-pixel 101R, the plurality of optical adjustment layers 21R is stacked on the first surface side of the first layer 122 to form a second layer 121R.

The first layers 122 may be layers of the same quality of material in all of the sub-pixels 101, or may be different layers. Furthermore, as described in the second embodiment, the plurality of optical adjustment layers 21B, 21G, and 21R included in the second layers 121B, 121G, and 121R is arranged in a state of being separated from each other along the light emitting surface direction of the light emitting element 104. The size and pitch of the optical adjustment layer 21 are set according to the color type of the sub-pixel 101, and are set to predetermined values in consideration of the resonance condition and the effective refractive index neff. A quality of material of the optical adjustment layer 21 is selected in consideration of the effective refractive index neff determined in a case where the resonator structure 19 of the sub-pixel 101 satisfies the resonance condition.

According to Modification 2, a layer configuration of the refractive index adjustment layer 20 can be increased, whereby the degree of freedom in design can be improved.

### (Modification 3)

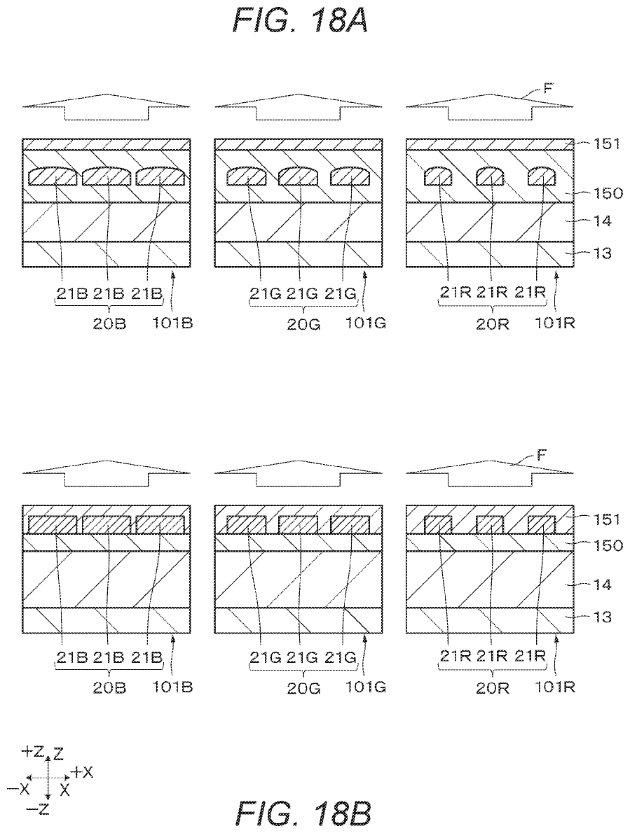

In the display device 10 according to the second embodiment, as illustrated in FIG. 18A, a shape of the optical adjustment layer 21 may be a chamfered shape with rounded corner positions (Modification 3).

When the optical adjustment layer 21 is subjected to division processing, it is easy to form the shape of the optical adjustment layer 21 into a shape with rounded corner positions, and thus, according to Modification 3, the display device 10 can be more easily manufactured.

### (Modification 4)

In the display device 10 according to the second embodiment, as illustrated in FIG. 18B, the second electrode 15 may include the transparent conductive layer 150 and the semi-transmissive reflective layer 151, and the plurality of optical adjustment layers 21 may be arranged at a position between the transparent conductive layer 150 and the semi-transmissive reflective layer 151 (Modification 4).

According to the display device 10 according to Modification 4 illustrated in FIG. 18B, it is possible to omit a step of further forming the transparent conductive layer 150 after dividing and forming the optical adjustment layers 21 as illustrated in FIG. 15A. As described above, with simplification of the configuration of the display device 10, the manufacturing step is simplified, and the number of manufacturing steps can be reduced.

### (Modification 5)

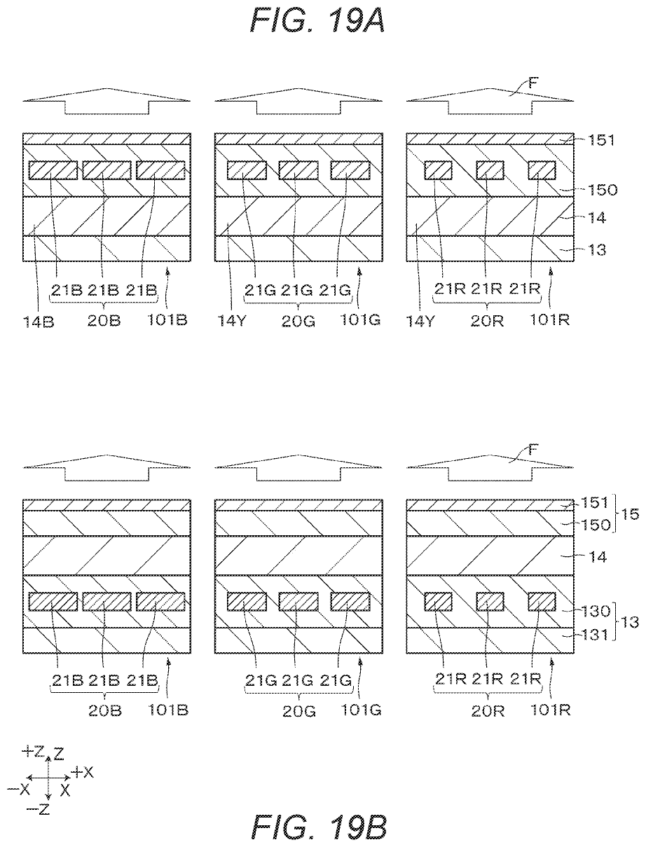

Also in the example of the display device 10 according to the second embodiment, similarly to the display device 10 according to the first embodiment, the emission color of the organic layer 14 provided in each of the sub-pixels 101B, 101G, and 101R is not limited to white of the same color. In the display device 10 according to the second embodiment, as illustrated in FIG. 19A, an emission color (first emission color) of the organic layer 14 provided in at least the sub-pixel 101 corresponding to one color type may be a color type different from an emission color (second emission color) of the organic layer 14 provided in the sub-pixels 101 corresponding to a plurality of other color types (Modification 5).

In the example of FIG. 19A, the organic layer 14 provided in the sub-pixel 101B is the organic layer 14B having blue as the emission color (first emission color). In this example, for the sub-pixel 101B, the optical adjustment layers 21B are included in the second electrode 15 (transparent conductive layer 150), and the resonator structure 19 is formed, but the present embodiment is not limited thereto, and the optical adjustment layers 21B may be omitted.

In the display device 10 according to Modification 5, the second emission color of the organic layer 14 provided in the sub-pixels 101 corresponding to the plurality of other color types is common among the sub-pixels 101 corresponding to the plurality of other color types. In the example of FIG. 19A, each of the organic layers 14 provided in the sub-pixels 101G and 101R is the organic layer 14Y having yellow as the emission color (second emission color). Furthermore, in the sub-pixels 101G and 101R, the optical adjustment layers 21G and 21R are included in the second electrode 15 (transparent conductive layer 150). The sizes and pitches of the optical adjustment layers 21G and 21R are determined to be different from each other (the effective refractive index neff is determined) so that the resonator structures 19G and 19R formed in the sub-pixels 101G and 101R cause green and red light to resonate, respectively (the resonance condition is satisfied).

According to the display device 10 of Modification 5, high luminous efficiency can be achieved for a predetermined color (blue in the example of FIG. 19A). Furthermore, for other colors (red and green in the example of FIG. 19A), by providing the different optical adjustment layers 21 according to the sub-pixels 101, it is possible to efficiently extract light of a color type according to the sub-pixel 101.

### (Modification 6)

In the display device 10 according to the second embodiment, as illustrated in FIG. 19B, the optical adjustment layers 21 may be included in the first electrode 13 (Modification 6). FIG. 19B illustrates an implementation example of the display device 10 according to Modification 6 of the second embodiment.

In the example of FIG. 19B, the first electrode 13 is an anode electrode including the transparent conductive layer 130 and the reflective layer 131, and the transparent conductive layer 130 is arranged closer to the organic layer 14. A metal such as Al is suitably used for the reflective layer 131. Furthermore, as the transparent conductive layer 130, a metal oxide film such as ITO or IZO is suitably used. Note that, in Modification 6, the second electrode 15 may include only the semi-transmissive reflective layer 151 in addition to a case of including a structure in which the transparent conductive layer 150 and the semi-transmissive reflective layer 151 are stacked as illustrated in FIG. 19B.

In the display device 10 according to Modification 6, the optical adjustment layers 21 are included in the transparent conductive layer 130. Various conditions (arrangement conditions) such as the pitch, the size, and the quality of material of the optical adjustment layers 21 are similar to those in a case where the optical adjustment layers 21 are included in the second electrode 15. That is, also in a case where the refractive index adjustment layer 20 is included in the first electrode 13, the arrangement conditions of the optical adjustment layers 21 are preferably determined so that the effective refractive index neff of the refractive index adjustment layer 20 is a predetermined value on the basis of the optical distance at which the resonance condition is satisfied in each of the resonator structures 19B, 19G, and 19R.

### (Modification 7)

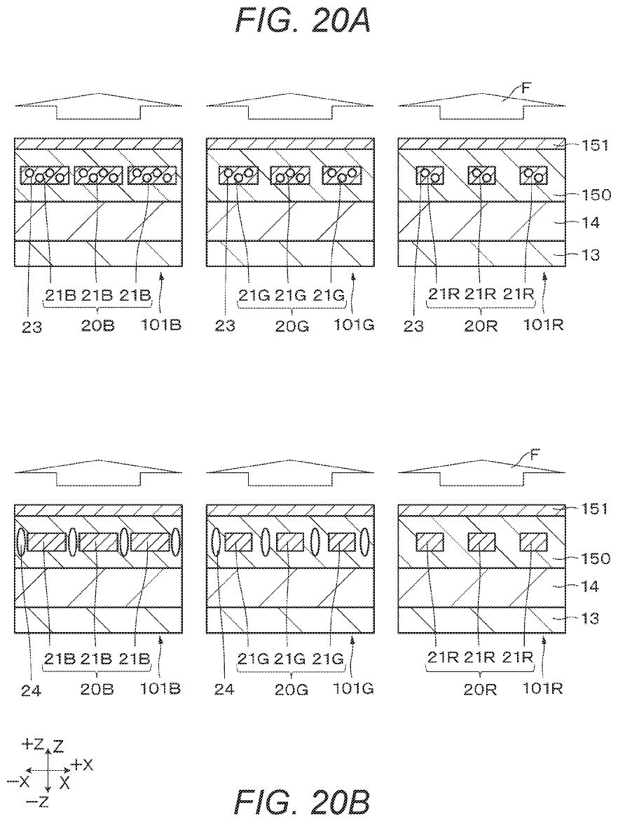

In the display device 10 according to the second embodiment, as illustrated in FIG. 20A, in a case where the second electrode 15 includes the transparent conductive layer 150 and the optical adjustment layer 21 is provided in the transparent conductive layer 150, the optical adjustment layer 21 may have the density reduction structure 23 (Modification 7). FIG. 20A illustrates an implementation example of the display device 10 according to Modification 7 of the second embodiment.

In the example of FIG. 20A, the optical adjustment layer 21 (21B, 21G, 21R) provided in each sub-pixel 101 has the density reduction structure 23.

As illustrated in the example of FIG. 20A, examples of the density reduction structure 23 can include, for example, a porous structure. The optical adjustment layer 21 has the density reduction structure 23, thereby being a layer in a sparse state (layer with low density), and the refractive index can be lowered. The function and effect of the density reduction structure 23 are similar to those described in the first embodiment.

Note that the display device 10 according to Modification 7 can be similarly applied to a case where the first electrode 13 includes the transparent conductive layer 130. That is, in a case where the optical adjustment layer 21 is provided in the transparent conductive layer 130, the optical adjustment layer 21 may have the density reduction structure 23.

### (Modification 8)

In the display device 10 according to the second embodiment, as illustrated in FIG. 20B, in a case where the second electrode 15 includes the transparent conductive layer 150 and the plurality of optical adjustment layers 21 is included in the transparent conductive layer 150, the transparent conductive layer 150 may include a void 24 (Modification 8). FIG. 20B illustrates an implementation example of the display device 10 according to Modification 8 of the second embodiment.

In the example of FIG. 20B, the transparent conductive layer 150 provided in each sub-pixel 101 includes the void 24. In the sub-pixels 101B and 101G, the void 24 is formed between the adjacent optical adjustment layers 21. In this example, in the sub-pixel 101R, formation of the void 24 between the adjacent optical adjustment layers 21 is avoided. However, this does not prohibit providing the void 24 in all the sub-pixels 101. The size of the void 24 may be determined according to the color type of the sub-pixel 101. Since the void 24 is formed between the adjacent optical adjustment layers 21 as described above, the value of the effective refractive index neff can be suppressed, and the degree of freedom of adjustment of the optical distance L is further improved. Furthermore, the value of the effective refractive index neff can be adjusted according to the size of the void 24. Specifically, in the example of FIG. 20B, the size of the individual void 24 formed in the sub-pixel 101B is larger than the size of the void 24 formed in the sub-pixel 101G.

### (Modification 9)

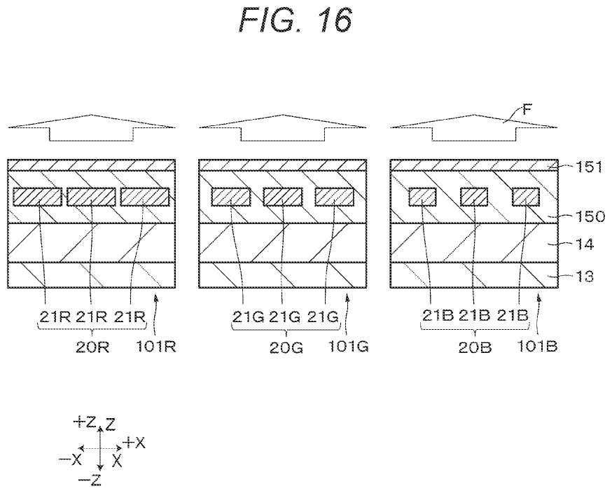

In the example of the display device according to the second embodiment, a case has been described where the sizes of the optical adjustment layer 21B, the optical adjustment layer 21G, and the optical adjustment layer 21R decrease in this order (the optical adjustment layer 21B is the largest), but the sizes are not limited thereto. For example, by using a material having a high refractive index as a material constituting the optical adjustment layers 21B, 21G, and 21R and appropriately selecting the resonance order in a case where the resonance conditions of the resonator structures 19B, 19G, and 19R are satisfied, the order of the sizes of the optical adjustment layer 21B, the optical adjustment layer 21G, and the optical adjustment layer 21R is changed as illustrated in FIG. 16. In FIG. 16, the sizes of the optical adjustment layer 21R, the optical adjustment layer 21G, and the optical adjustment layer 21B decrease in this order. This similarly applies to the pitch of the optical adjustment layers 21.

In the first embodiment, the second embodiment, and modifications accompanying each embodiment, an example in which the refractive index adjustment layer 20 is formed in the first electrode 13 or the second electrode 15 can be similarly applied to a case where the refractive index adjustment layer 20 is formed in both the first electrode 13 and the second electrode 15.

### 3. Third Embodiment

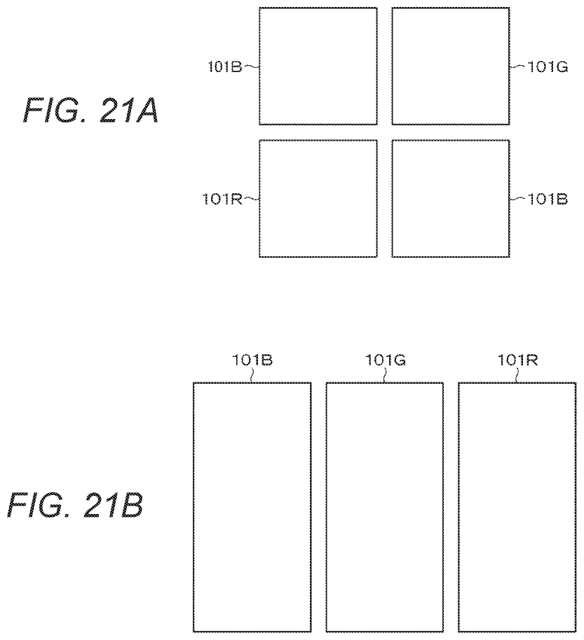

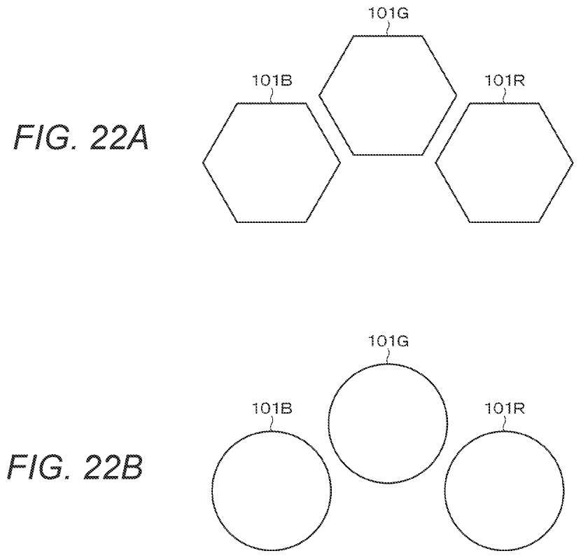

In the display device 10 described in the first embodiment and the second embodiment, as illustrated in FIG. 2 and the like, the sub-pixels 101 forming one pixel are formed side by side. As illustrated in FIGS. 21, 22, and the like, the shape of each sub-pixel 101 is not particularly limited to the example of FIG. 2 and the like (third embodiment). FIGS. 21 and 22 are plan views illustrating implementation examples of a layout of sub-pixels forming one pixel. In the display device 10, the shape of the sub-pixel 101 may be a stripe shape as illustrated in FIG. 21B, a polygonal shape as illustrated in FIG. 22A, or a circular shape as illustrated in FIG. 22B. Furthermore, in the display device 10, the layout of the sub-pixels 101 forming one pixel may be a square array as illustrated in FIG. 21A. In FIG. 21A, among four sub-pixels 101 arranged such that a quadrangular shape is formed when the centers of the sub-pixels 101 are connected, two sub-pixels 101 arranged on a diagonal line are the sub-pixels 101B, and two sub-pixels 101 arranged in another diagonal line are the sub-pixels 101R and 101G. Furthermore, as illustrated in FIGS. 22A and 22B, a layout pattern of the sub-pixels 101 forming one pixel may be a delta array including three sub-pixels 101B, 101G, and 101R arranged such that a triangular shape is formed when the centers of the sub-pixels 101 are connected.

### 4. Fourth Embodiment

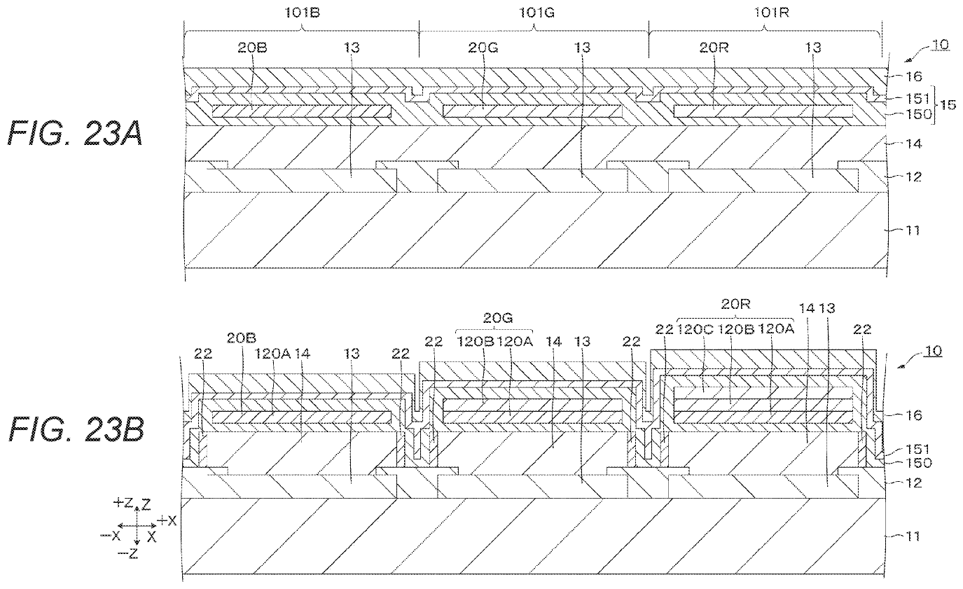

In the display device 10 described in the first to third embodiments, the organic layer 14 is individually separated (divided) for each sub-pixel 101, but the display device 10 is not limited thereto. As illustrated in FIG. 23A, the organic layer 14 may be continuously formed regardless of the sub-pixel 101 (fourth embodiment). FIG. 23A is a cross-sectional view illustrating an implementation example of a display device 10 according to the fourth embodiment. In FIG. 23A, the organic layer 14 is a common layer common to all the sub-pixels 101B, 101G, and 101R. Since the organic layer 14 is the common layer, the number of manufacturing steps can be reduced, and the ease of manufacturing can be improved. Furthermore, in FIG. 23A, the second electrode 15 is also a common electrode common to all the sub-pixels 101B, 101G, and 101R. The refractive index adjustment layers 20B, 20G, and 20R corresponding to the respective sub-pixels 101 are included at predetermined positions of the common electrode.

However, from a viewpoint of suppressing a leakage current between the sub-pixels 101 and a viewpoint of improving the light extraction efficiency due to reflection on the side end surface formed between the sub-pixels 101, it is more preferable that the organic layer 14 is separated for each sub-pixel 101 as in the first embodiment.

### 5. Fifth Embodiment

In the display device 10 described in the first to fourth embodiments, the thickness of the transparent conductive layer 150 in the second electrode 15 may be set to a constant value between different sub-pixels 101 (fifth embodiment). In the fifth embodiment, the thickness of the transparent conductive layer 150 in the second electrode 15 is made uniform between the different sub-pixels 101, whereby it is easy to align resistance states between the sub-pixels 101, and it is easy to adjust the optical distance L. In the fifth embodiment, as illustrated in FIG. 23B, in particular, in a case where the refractive index adjustment layer 20 has a multilayer structure or the like, a level difference between the sub-pixels 101 may be generated; however, as compared with a case where the refractive index adjustment layer 20 is not included, the level difference between the sub-pixels 101 can be reduced. Note that FIG. 23B is a cross-sectional view illustrating an implementation example of a case (fifth embodiment) where the refractive index adjustment layer 20 has a multilayer structure and the thickness of the transparent conductive layer 150 is uniform in the display device 10.

### 6. Sixth Embodiment

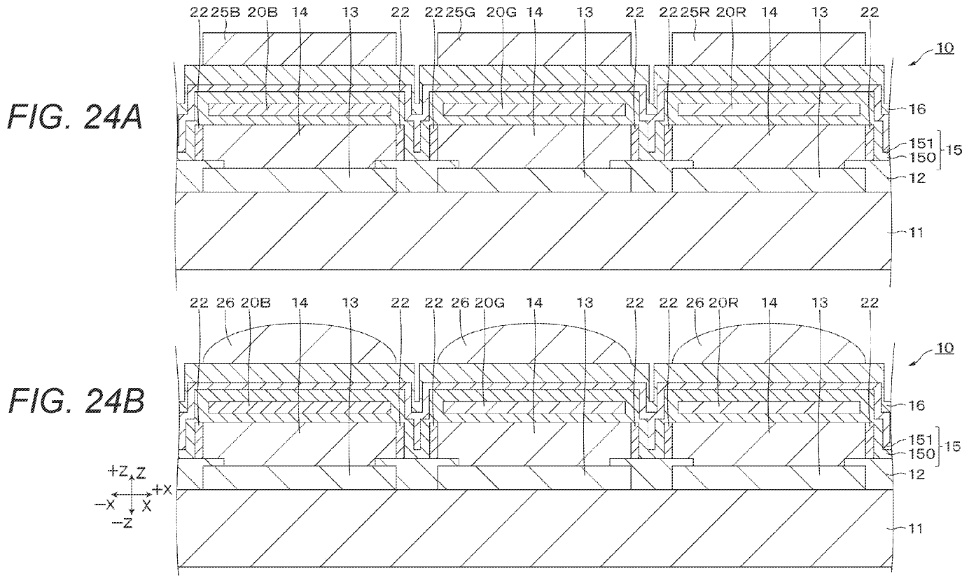

As illustrated in FIG. 24A, a color filter 25 may be further formed in the display device 10 illustrated in the first to fifth embodiments (sixth embodiment). FIG. 24A is a cross-sectional view illustrating an implementation example of a display device 10 according to the sixth embodiment.

### (Color Filter)

The color filter 25 is provided on the first surface side (upper side, +Z direction side) of the protective layer 16. The color filter 25 is an on-chip color filter (OCCF). The color filter 25 is provided according to the color type of the sub-pixel 101. Examples of the color filters 25 include, for example, a red color filter (red filter 25R), a green color filter (green filter 25G), and a blue color filter (blue filter 25B) in the example of FIG. 24A. The red filter 25R, the green filter 25G, and the blue filter 25B are provided in the sub-pixels 101R, 101G, and 101B, respectively. The color filter 25 is provided in the display device 10, whereby the color purity can be further improved. Note that a flattening layer may be formed on the color filter 25, and the counter substrate 18 may be further provided on the flattening layer with the filling resin layer 17 interposed therebetween (not illustrated). The flattening layer may include a similar material to the filling resin layer 17.

### 7. Seventh Embodiment

As illustrated in FIG. 24B, a lens 26 may be further formed in the display device 10 illustrated in the first to sixth embodiments (seventh embodiment). FIG. 24B is a cross-sectional view illustrating an implementation example of a display device 10 according to the seventh embodiment.

### (Lens)

The lens 26 is provided on the first surface side (upper side, +Z direction side) of the protective layer 16. The lens 26 is an on-chip lens (OCL). The lens 26 is provided on the first surface side of each sub-pixel 101.

In the example of FIG. 24B, the lens 26 is arranged in each sub-pixel 101, and is formed in a convex shape that is convex in a direction away from the drive substrate 11. The display device 10 includes the lens 26, whereby the light extraction efficiency can be improved. Note that the lens 26 may be formed in a part of the sub-pixel 101.

### 8. Application Examples

### (Electronic Device)

A display device 10 according to one of the above-described embodiments may be provided in various electronic devices. Especially, this is preferably provided in an electronic viewfinder of a video camera or a single-lens reflex camera, a head mounted display, or the like in which high resolution is required, used for enlarging near the eyes.

### Specific Example 1

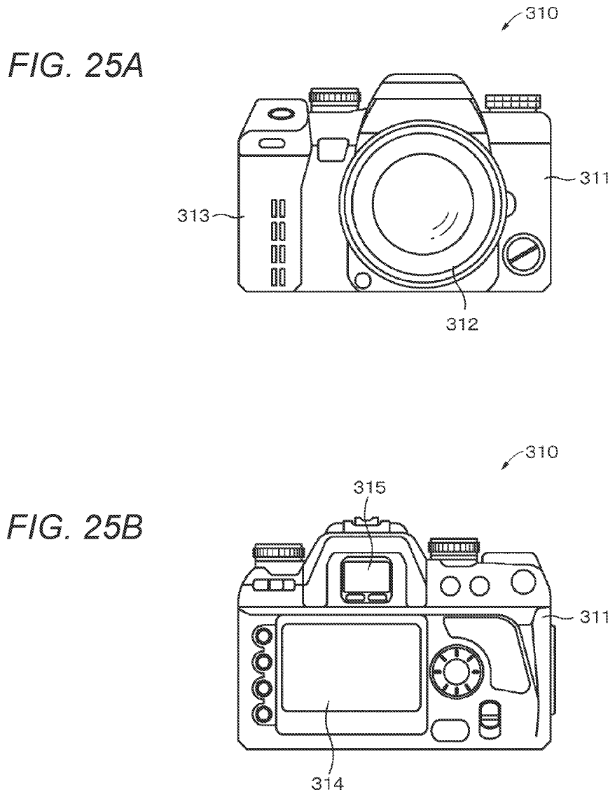

FIG. 25A is a front view illustrating an example of an external appearance of a digital still camera 310. FIG. 25B is a rear view illustrating an example of an external appearance of the digital still camera 310. The digital still camera 310 is of a lens interchangeable single lens reflex type, and includes an interchangeable imaging lens unit (interchangeable lens) 312 substantially at the center in front of a camera main body portion (camera body) 311, and a grip portion 313 to be held by a photographer on a front left side.

A monitor 314 is provided at a position shifted to the left from the center of a rear surface of the camera main body portion 311. An electronic viewfinder (eyepiece window) 315 is provided above the monitor 314. By looking through the electronic viewfinder 315, the photographer can visually confirm a light image of a subject guided from the imaging lens unit 312 and determine a picture composition. As the electronic viewfinder 315, any display device 10 according to one of the above-described embodiments and modifications thereof may be used.

### Specific Example 2

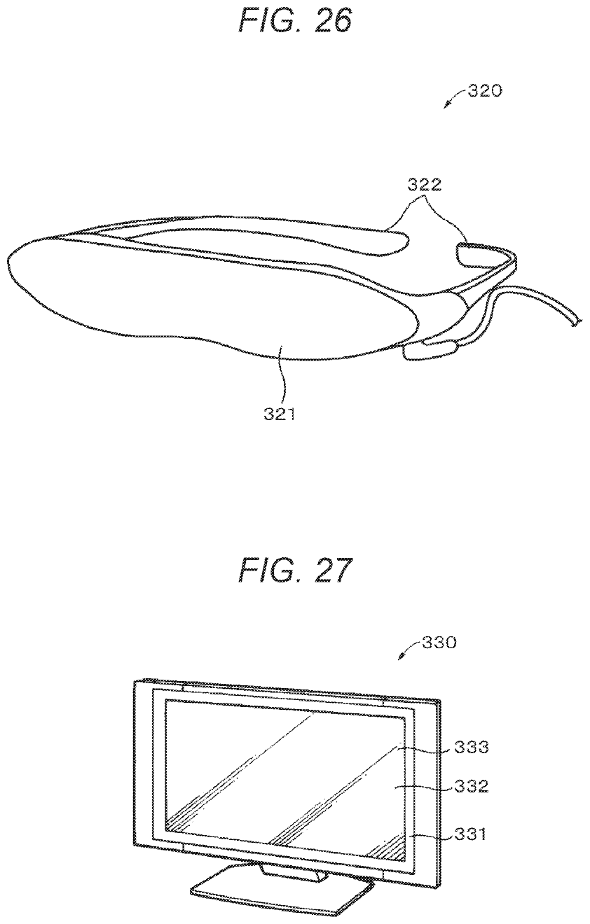

FIG. 26 is a perspective view illustrating an example of an external appearance of a head mounted display 320. The head mounted display 320 includes, for example, ear hooking portions 322 to be worn on the head of a user on both sides of a glass-shaped display unit 321. As the display unit 321, any display device 10 according to one of the above-described embodiments and modifications thereof may be used.

### Specific Example 3

FIG. 27 is a perspective view illustrating an example of an external appearance of a television device 330. The television device 330 includes, for example, a video display screen unit 331 including a front panel 332 and a filter glass 333, and the video display screen unit 331 includes any display device 10 according to one of the above-described embodiments and modifications thereof.

Although the display devices and the application examples according to the first to seventh embodiments and each modification of the present disclosure have been specifically described above, the present disclosure is not limited to the display devices and the application examples according to the first to seventh embodiments and each modification described above, and various modifications based on the technical idea of the present disclosure are possible.

For example, the configurations, methods, steps, shapes, materials, numerical values, and the like given in the display devices and the application examples according to the first to seventh embodiments and each modification are merely examples, and different configurations, methods, steps, shapes, materials, numerical values, and the like may be used as necessary.

The configurations, methods, steps, shapes, materials, numerical values, and the like of the display devices and the application examples according to the first to seventh embodiments and each modification can be combined with each other without departing from the gist of the present disclosure.

The materials exemplified in the display devices and the application examples according to the first to seventh embodiments and each modification can be used alone or in combination of two or more unless otherwise specified.

Furthermore, the present disclosure can also adopt the following configurations.
(1)

A display device including
a plurality of sub-pixels corresponding to a plurality of color types, in which each of the sub-pixels includes a light emitting element including a first electrode, an organic layer, and a second electrode, and
in at least the sub-pixels corresponding to one color type, a resonator structure that causes emitted light from the organic layer to resonate is formed and a refractive index adjustment layer is included in at least one of the first electrode or the second electrode.
(2)

The display device according to (1), in which
a composition of the refractive index adjustment layer is different for each color type of the sub-pixels.
(3)

The display device according to (1) or (2), in which
the refractive index adjustment layer has a multilayer structure.
(4)

The display device according to any one of (1) to (3), in which
the second electrode is a cathode electrode including a transparent conductive layer and a semi-transmissive reflective layer, and
the refractive index adjustment layer is provided in the transparent conductive layer.
(5)

The display device according to any one of (1) to (3), in which
the second electrode is a cathode electrode including a transparent conductive layer and a semi-transmissive reflective layer, and
the refractive index adjustment layer is arranged at a position between the transparent conductive layer and the semi-transmissive reflective layer.
(6)

The display device according to any one of (1) to (5), in which
arrangement of the refractive index adjustment layer is avoided in at least the sub-pixels corresponding to one color type different from a color type of the sub-pixels in which the refractive index adjustment layer is arranged.
(7)

The display device according to any one of (1) to (6), in which
a first emission color of the organic layer provided in at least the sub-pixels corresponding to one color type is a color type different from a second emission color of the organic layer provided in the sub-pixels corresponding to a plurality of other color types,
the second emission color of the organic layer provided in the sub-pixels corresponding to the plurality of other color types is common among the sub-pixels corresponding to the plurality of other color types, and
in each of the sub-pixels corresponding to the plurality of other color types, the resonator structure is formed and the refractive index adjustment layer is provided.
(8)

The display device according to any one of (1) to (7), in which
the first electrode is an anode electrode including a transparent conductive layer and a reflective layer, and
the refractive index adjustment layer is provided in the transparent conductive layer.
(9)

The display device according to any one of (1) to (8), in which
one or both of the first electrode and the second electrode include a transparent conductive layer, and the refractive index adjustment layer is provided in the transparent conductive layer, and
the refractive index adjustment layer has a density reduction structure.
(10)

The display device according to (1), in which
the refractive index adjustment layer includes a plurality of optical adjustment layers, and
a plurality of the optical adjustment layers is arranged in a state of being separated from each other along a light emitting surface direction of the light emitting element.
(11)

The display device according to (1), in which
a plurality of the refractive index adjustment layers has a multilayer structure,
at least one layer forming a plurality of the refractive index adjustment layers includes a plurality of optical adjustment layers, and
a plurality of the optical adjustment layers is arranged in a state of being separated from each other along a light emitting surface direction of the light emitting element.
(12)

The display device according to (10) or (11), in which
the second electrode is a cathode electrode including a transparent conductive layer and a semi-transmissive reflective layer, and
a plurality of the optical adjustment layers is provided in the transparent conductive layer.
(13)

The display device according to any one of (10) to (12), in which
in the sub-pixels corresponding to each color type, a pitch of a plurality of the optical adjustment layers is set to a value less than or equal to a peak wavelength of light corresponding to the color type of the sub-pixels.
(14)

The display device according to any one of (10) to (13), in which
one or both of the first electrode and the second electrode include a transparent conductive layer, and a plurality of the optical adjustment layers is provided in the transparent conductive layer, and
a refractive index of a plurality of the optical adjustment layers and a refractive index of the transparent conductive layer are different from each other.
(15)

The display device according to any one of (10) to (14), in which
arrangement of a plurality of the optical adjustment layers is avoided in at least the sub-pixels corresponding to one color type different from a color type of the sub-pixels in which the refractive index adjustment layer is arranged.
(16)

The display device according to any one of (10) to (15), in which
the first electrode is an anode electrode including a transparent conductive layer and a reflective layer, and
a plurality of the optical adjustment layers is provided in the transparent conductive layer.
(17)

The display device according to any one of (10) to (16), in which
one or both of the first electrode and the second electrode include a transparent conductive layer, and a plurality of the optical adjustment layers is provided in the transparent conductive layer, and
the transparent conductive layer includes a void.
(18)

The display device according to any one of (10) to (17), in which
one or both of the first electrode and the second electrode include a transparent conductive layer, and a plurality of the optical adjustment layers is provided in the transparent conductive layer, and
the optical adjustment layer includes a density reduction structure.
(19)

An electronic device including
the display device according to any one of (1) to (18).
(20)

A method of manufacturing a display device, including:
forming an optical adjustment layer on a transparent conductive layer;
collectively dividing the optical adjustment layer at a pitch corresponding to each of sub-pixels; and
forming a semi-transmissive reflective layer to cover the optical adjustment layer divided.

### REFERENCE SIGNS LIST

10 Display device
11 Drive substrate
12 Insulating layer
13 First electrode
14 Organic layer
15 Second electrode
16 Protective layer
17 Filling resin layer
18 Counter substrate
19B Resonator structure
19G Resonator structure
19R Resonator structure
20B Refractive index adjustment layer
20G Refractive index adjustment layer
20R Refractive index adjustment layer
21B Optical adjustment layer
21G Optical adjustment layer
21R Optical adjustment layer
22 Side wall layer
23 Density reduction structure
24 Void
101 Sub-pixel
101B Sub-pixel
101G Sub-pixel
101R Sub-pixel
104 Light emitting element
104B Light emitting element
104G Light emitting element
104R Light emitting element
130 Transparent conductive layer
131 Reflective layer
150 Transparent conductive layer
151 Semi-transmissive reflective layer
Nf Refractive index adjustment layer

What is claimed is:

1. A display device, comprising
a plurality of sub-pixels corresponding to a plurality of color types, wherein
each of the sub-pixels includes a light emitting element including a first electrode, an organic layer, and a second electrode, and
in at least the sub-pixels corresponding to one color type, a resonator structure that causes emitted light from the organic layer to resonate is formed and a refractive index adjustment layer is included in at least one of the first electrode or the second electrode.

2. The display device according to claim 1, wherein
a composition of the refractive index adjustment layer is different for each color type of the sub-pixels.

3. The display device according to claim 1, wherein
the refractive index adjustment layer has a multilayer structure.

4. The display device according to claim 1, wherein
the second electrode is a cathode electrode including a transparent conductive layer and a semi-transmissive reflective layer, and
the refractive index adjustment layer is provided in the transparent conductive layer.

5. The display device according to claim 1, wherein
the second electrode is a cathode electrode including a transparent conductive layer and a semi-transmissive reflective layer, and
the refractive index adjustment layer is arranged at a position between the transparent conductive layer and the semi-transmissive reflective layer.

6. The display device according to claim 1, wherein
arrangement of the refractive index adjustment layer is avoided in at least the sub-pixels corresponding to one color type different from a color type of the sub-pixels in which the refractive index adjustment layer is arranged.

7. The display device according to claim 1, wherein
a first emission color of the organic layer provided in at least the sub-pixels corresponding to one color type is a color type different from a second emission color of the organic layer provided in the sub-pixels corresponding to a plurality of other color types,
the second emission color of the organic layer provided in the sub-pixels corresponding to the plurality of other color types is common among the sub-pixels corresponding to the plurality of other color types, and
in each of the sub-pixels corresponding to the plurality of other color types, the resonator structure is formed and the refractive index adjustment layer is provided.

8. The display device according to claim 1, wherein
the first electrode is an anode electrode including a transparent conductive layer and a reflective layer, and
the refractive index adjustment layer is provided in the transparent conductive layer.

9. The display device according to claim 1, wherein
one or both of the first electrode and the second electrode include a transparent conductive layer, and the refractive index adjustment layer is provided in the transparent conductive layer, and
the refractive index adjustment layer has a density reduction structure.

10. The display device according to claim 1, wherein
the refractive index adjustment layer includes a plurality of optical adjustment layers, and
a plurality of the optical adjustment layers is arranged in a state of being separated from each other along a light emitting surface direction of the light emitting element.

11. The display device according to claim 1, wherein
the refractive index adjustment layer has a multilayer structure,
at least one layer forming the refractive index adjustment layer includes a plurality of optical adjustment layers, and
a plurality of the optical adjustment layers is arranged in a state of being separated from each other along a light emitting surface direction of the light emitting element.

12. The display device according to claim 10, wherein
the second electrode is a cathode electrode including a transparent conductive layer and a semi-transmissive reflective layer, and
a plurality of the optical adjustment layers is provided in the transparent conductive layer.

13. The display device according to claim 10, wherein
in the sub-pixels corresponding to each color type, a pitch of a plurality of the optical adjustment layers is set to a value less than or equal to a peak wavelength of light corresponding to the color type of the sub-pixels.

14. The display device according to claim 10, wherein
one or both of the first electrode and the second electrode include a transparent conductive layer, and a plurality of the optical adjustment layers is provided in the transparent conductive layer, and
a refractive index of a plurality of the optical adjustment layers and a refractive index of the transparent conductive layer are different from each other.

15. The display device according to claim 10, wherein
arrangement of a plurality of the optical adjustment layers is avoided in at least the sub-pixels corresponding to one color type different from a color type of the sub-pixels in which the refractive index adjustment layer is arranged.

16. The display device according to claim 10, wherein
the first electrode is an anode electrode including a transparent conductive layer and a reflective layer, and
a plurality of the optical adjustment layers is provided in the transparent conductive layer.

17. The display device according to claim 10, wherein
one or both of the first electrode and the second electrode include a transparent conductive layer, and a plurality of the optical adjustment layers is provided in the transparent conductive layer, and
the transparent conductive layer includes a void.

18. The display device according to claim 10, wherein
one or both of the first electrode and the second electrode include a transparent conductive layer, and a plurality of the optical adjustment layers is provided in the transparent conductive layer, and
the optical adjustment layer includes a density reduction structure.

19. An electronic device, comprising
the display device according to claim 1.

20. A method of manufacturing a display device, comprising:
forming an optical adjustment layer on a transparent conductive layer;
collectively dividing the optical adjustment layer at a pitch corresponding to each of sub-pixels; and
forming a semi-transmissive reflective layer to cover the optical adjustment layer divided.
